(19) United States
(12) Patent Application Publication
(10) Pub. No.: US 2026/0040763 A1
(43) Pub. Date: Feb. 5, 2026

(54) DISPLAY PANEL INCLUDING SILICON SEMICONDUCTOR LAYER HAVING AN EXTENSION PORTION AND ELECTRONIC DEVICE INCLUDING THE SAME

(71) Applicant: SAMSUNG DISPLAY CO., LTD., YONGIN-SI (KR)

(72) Inventors: Heyjin Shin, YONGIN-SI, GYEONGGI-DO (KR); Daehyun Kim, YONGIN-SI, GYEONGGI-DO (KR); Mihae Kim, YONGIN-SI, GYEONGGI-DO (KR); Sunghwan Kim, YONGIN-SI, GYEONGGI-DO (KR); Hyunae Park, YONGIN-SI, GYEONGGI-DO (KR); Changkyu Jin, YONGIN-SI, GYEONGGI-DO (KR)

(21) Appl. No.: 19/288,117

(22) Filed: Aug. 1, 2025

(30) Foreign Application Priority Data
Aug. 2, 2024 (KR) 10-2024-0103444
Feb. 27, 2025 (KR) 10-2025-0026023

(51) Int. Cl. H10K 59/121; H10K 59/131

(52) U.S. Cl. CPC H10K 59/1213; H10K 59/131

(57) ABSTRACT

A display panel includes first transistors arranged adjacent to each other in a first direction and a silicon semiconductor layer including a main portion extending in the first direction and an extension portion extending in a second direction crossing the first direction. The extension portion is disposed between the first transistors, in a plan view.

### CROSS-REFERENCE TO RELATED APPLICATIONS

The present application claims priority under 35 U.S.C. § 119 to Korean Patent Application No. 10-2024-0103444, filed on Aug. 2, 2024 and Korean Patent Application No. 10-2025-0026023, filed on Feb. 27, 2025, the entire contents of which are herein incorporated by reference.

### TECHNICAL FIELD

The present disclosure relates to a display panel, and more specifically, to a display panel including a silicon semiconductor layer having an extension portion and an electronic device including the display panel.

### DISCUSSION OF THE RELATED ART

Display panels have been used in various electronic devices. As display panels have progressed, they have been made to have higher resolutions while also making improvements to overall display quality. To display higher-quality images at higher resolutions, the physical size of each pixel is reduced, and thus, a higher density of electronic elements is required.

### SUMMARY

A display panel includes a plurality of first transistors arranged adjacent to each other in a first direction and a silicon semiconductor layer including a main portion extending in the first direction and an extension portion extending in a second direction crossing the first direction. The extension portion is disposed between neighboring first transistors of the plurality of first transistors, in a plan view.

Each of the plurality of first transistors may include a first semiconductor layer and a first gate electrode disposed over the first semiconductor layer and overlapping the first semiconductor layer.

The first semiconductor layer may include an oxide semiconductor.

The display panel may further include a gate insulating layer covering the silicon semiconductor layer. The first semiconductor layer may be disposed over the gate insulating layer.

The display panel may further include a plurality of capacitor electrodes disposed between the gate insulating layer and the first semiconductor layer. The capacitor electrodes of the plurality of capacitor electrodes may be spaced apart from each other and may correspond to the first transistors of the plurality of first transistors.

In the plan view, the extension portion may be disposed between neighboring capacitor electrodes of the plurality of capacitor electrodes.

An end of the extension portion in the second direction may coincide with an end in the second direction of a portion of each of the plurality of first capacitor electrodes adjacent to the extension portion.

The display panel may further include a plurality of shield layers disposed between the capacitor electrodes and the first transistors.

Each of the plurality of shield layers may be electrically connected to a corresponding capacitor electrode among the plurality of capacitor electrodes.

The display panel may further include a plurality of second transistors corresponding to the plurality of first transistors and a plurality of data lines corresponding to the plurality of second transistors. Each second transistor of the plurality of second transistors may have a first end electrically connected to a corresponding data line among the plurality of data lines, and a second end electrically connected to a first gate electrode of a corresponding first transistor among the plurality of first transistors. A second semiconductor layer of each of the plurality of second transistors may be disposed on a same layer as a first semiconductor layer of each of the plurality of first transistors.

The display panel may further include a driving voltage line electrically connected to the silicon semiconductor layer.

The driving voltage line may be disposed over the silicon semiconductor layer.

The display panel may further include emission control transistors including a first portion of the main portion disposed at a first side of the extension portion, and a second portion of the main portion disposed at a second side of the extension portion. Each of the emission control transistors may be electrically connected to a corresponding first transistor among the plurality of first transistors.

The display panel may further include a plurality of connection electrodes electrically connecting each of the first and second portions of the main portion to a corresponding first transistor among the plurality of first transistors.

An electronic device includes a display panel and a lower cover forming an exterior of the electronic device. The lower cover includes an opening exposing a portion of the display panel. The display panel includes a plurality of first transistors arranged adjacent to each other in a first direction and a silicon semiconductor layer including a main portion extending in the first direction and an extension portion extending in a second direction crossing the first direction. The extension portion is disposed between neighboring first transistors of the plurality of first transistors, in a plan view.

Each of the plurality of first transistors may include a first semiconductor layer and a first gate electrode disposed over the first semiconductor layer and overlapping the first semiconductor layer.

The first semiconductor layer may include an oxide semiconductor.

The electronic device may further include a gate insulating layer covering the silicon semiconductor layer. The first semiconductor layer may be disposed over the gate insulating layer. A plurality of capacitor electrodes may be disposed between the gate insulating layer and the first semiconductor layer, spaced apart from each other, and corresponding to the plurality of first transistors.

In the plan view, the extension portion may be disposed between neighboring capacitor electrodes of the plurality of capacitor electrodes.

The electronic device may further include a driving voltage line electrically connected to the silicon semiconductor layer.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a block diagram of an electronic device according to an embodiment of the present invention;

FIG. 2 is a perspective view of electronic devices according to embodiments of the present invention;

FIG. 3 is a perspective view showing a case where electronic devices according to embodiments of the present invention are wearable electronic devices;

FIG. 4 is a perspective view showing a case where electronic devices according to embodiments of the present invention are vehicle electronic devices;

FIG. 5 is a plan view of a display module according to an embodiment of the present invention;

FIG. 6 is a side view of the display module of FIG. 5;

FIG. 7 is a plan view of the display module of FIG. 5;

FIG. 8 is an enlarged plan view of a region A of the display module of FIG. 7;

FIG. 9 is an enlarged plan view of a portion of a display panel according to an embodiment of the present invention;

FIG. 10 is an equivalent circuit diagram of a pixel disposed in a display area of the display module of FIG. 7;

FIG. 11 is a plan view showing positions of transistors, capacitors and the like in pixels disposed in a display area of the display module of FIG. 7;

FIGS. 12 to 20 are plan views of elements such as transistors and capacitors, for each layer, of the display panel shown in FIG. 11;

FIG. 21 is a plan view of pixel electrodes of the display panel of FIG. 11; and

FIG. 22 is a cross-sectional view taken along line B-B′ of FIG. 11.

### DETAILED DESCRIPTION OF THE DRAWINGS

As the present invention allows for various changes and numerous embodiments, certain embodiments will be illustrated in the drawings and described in the detailed description. Effects and features of the present invention, and methods for achieving them will be clarified with reference to embodiments described below in detail with reference to the drawings. However, the present invention is not necessarily limited to embodiments described below and may be implemented in various forms.

Hereinafter, embodiments of the present invention will be described with reference to the accompanying drawings, wherein, like or corresponding elements may be given like reference numerals when describing with reference to the drawings, and to the extent that an element is not described in detail with respect to this figure, it may be understood that the element is at least similar to a corresponding element that has been described elsewhere within the present disclosure.

In embodiments below, when various elements such as a layer, a region, a plate, and the like are disposed “on” another element, not only may the elements be disposed “directly on” the other element, but another element may be interposed therebetween. In addition, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

In an embodiment below, an x axis, a y axis, and a z axis are not necessarily limited to three axes of the Cartesian rectangular coordinate system, and may be interpreted in a broader sense including the same. For example, the x axis, y axis, and z axis may be perpendicular to one another, or may represent different directions that are not necessarily perpendicular to one another.

In embodiments below, such terms as first and second are not necessarily used in a limited meaning and may be used for the purpose of distinguishing one element from another.

In embodiments below, the terms “comprise,” or “include” as used herein specify the presence of stated features or elements but do not preclude the addition of one or more other features or elements.

In the present specification, “A and/or B” means A or B, or A and B. In addition, “at least one of A and B” means A or B, or A and B.

In embodiments below, when a layer, region, or element is referred to as being connected, it includes not only a case where the layer, region, or element is directly connected, but also a case where the layer, region, or element is indirectly connected with another layer, region, or element interposed therebetween. For example, in the present specification, when a layer, region, or element is referred to as being electrically connected, it represents a case where the layer, region, or element is directly electrically connected and/or a case where the layer, region, or element is indirectly electrically connected with another layer, region, or element interposed therebetween.

Embodiments of the present disclosure relate to a high-performance display panel and the integration of this panel into an electronic device. According to these approaches, an arrangement of semiconductor layers and transistor configurations may be used to optimize the space within pixel circuits, reduce interference, and enhance image quality. For example, the display panel may include first transistors arranged side-by-side along a first direction, and a silicon semiconductor layer that include a main portion extending in that same direction and an extension portion running perpendicularly thereto. This extension portion is placed between the first transistors, in a plan view. This design allows for better use of available space in compact areas, such as high-resolution displays, and helps manage manufacturing challenges related to patterning and defects.

The silicon semiconductor layer may overlap a bottom metal layer that acts as a shield, which protects the circuit from electrostatic discharge (ESD) and minimizes light interference. Additionally, oxide semiconductor layers may be used for other transistors in the pixel circuit, taking advantage of their high carrier mobility and low leakage properties. The display panel may also be equipped with various shielding and capacitor layers that are strategically positioned to enhance performance and stability. For example, shield layers are electrically connected to capacitor electrodes to further minimize electrical noise and improve display clarity.

In terms of integration into devices, this advanced display panel is designed to be flexible and suitable for a range of electronic devices, including smartphones, tablets, TVs, smartwatches, and even vehicle-mounted systems. Various structural regions of the panel may be used, such as display, peripheral, and sub-regions, and there may be folding or bending regions, allowing for innovative form factors. A multi-layer circuit and display structure, with transistors and capacitors organized across multiple conductive and insulating layers, may allow the device to maintain high resolution and reliable operation in demanding physical configurations. This design not only enhances image quality but also supports new applications in both consumer electronics and specialty devices like transparent displays and wearable devices.

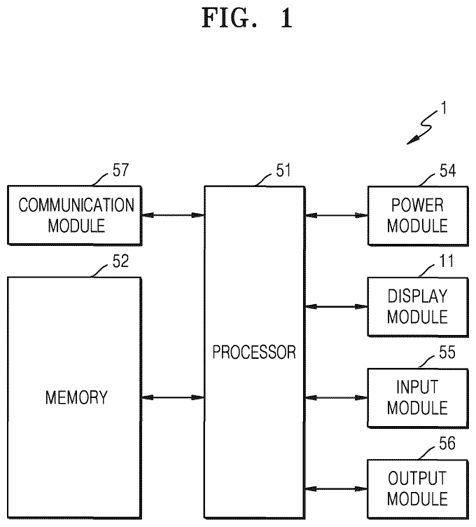

FIG. 1 is a schematic block diagram of an electronic device 1 according to an embodiment of the present invention. The electronic device 1, according to an embodiment, may be a display device, or may further include a module and the like having additional function other than a display module 11.

As shown in FIG. 1, the electronic device 1, according to an embodiment, may include the display module 11, a processor 51, a memory 52, a power module 54, an input module 55, an output module 56, and a communication module 57.

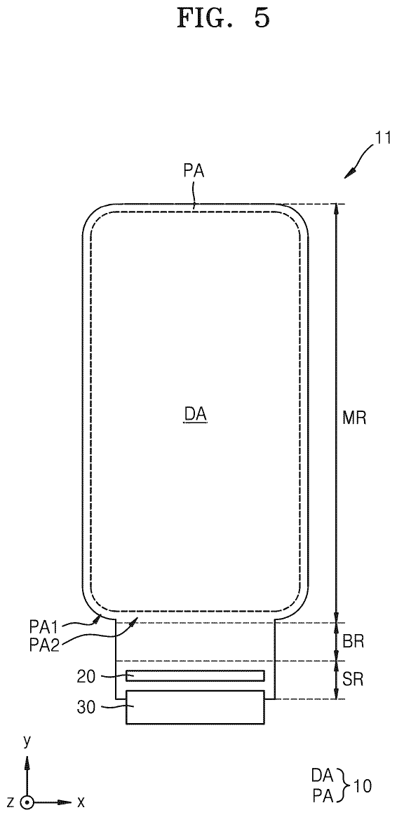

The display module 11 may include a display panel 10 (see FIG. 5) as described below. As an example, the display module 11 may include the display panel 10 and a data driver 20 (see FIG. 5) mounted thereon and the like. The display panel 10 is described below.

The processor 51 may control most of elements of the electronic device 1. As an example, the processor 51 may output digital video data to the display module 11 such that the display module 11 displays images, and may receive input data from the input module 55 to allow a function corresponding to the relevant data to be performed by the electronic device 1. The processor 51 may include at least one of a central processing unit (CPU), an application processor (AP), a graphic processing unit (GPU), a communication processor (CP), an image signal processor (ISP), and a controller.

When needed, the processor 51 may be divided into two or more portions in a functional or structural viewpoint. Thus, the processor 51 may be made up of a plurality of processing devices that operate together. As an example, the processor 51 may include a main processor in the form of a first driving chip including a central processing unit, and an auxiliary processor in the form of a second driving chip, which is a portion of the display module 11. The auxiliary processor in the form of the second driving chip may include a controller receiving image signals from the main processor and processing image signals to match interface specifications of the display panel 10 included in the display module 11.

The memory 52 may include at least one of a non-volatile memory, such as flash memory, and a volatile memory, such as random-access memory (RAM). The memory 52 may store data information required for operations of the processor 51 or the display module 11. When the processor 51 executes an application stored in the memory 52, data signals for images and/or an input control signal may be transferred to the display module 11, and the display module 11 may process provided signals and output image information.

The power module 54 may include a power supply module such as a power adapter or a battery unit, and a power converting module converting power supplied by the power supply module and generating power required for operations of the electronic device 1. Power conversion by the power converting module may include DC-DC conversion, AC-DC conversion, and DC-AC conversion. However, the present invention is not necessarily limited thereto.

The input module 55 may provide input information to the processor 51 and/or the display module 11. The input module 55 may include not only a physical button, a keyboard, and a microphone, but also various types of sensor modules. Examples of the sensor module may include a touch sensor, a pressure sensor, a distance sensor, a position sensor, a digitizer, a motion recognition sensor, a camera sensor, a light reception sensor, a photoelectric conversion sensor, and/or a temperature sensor. In addition, the sensor module may include biometric sensors such as a blood pressure sensor, a blood sugar sensor, an electrocardiogram sensor, and/or a heart rate sensor.

The output module 56 may receive information other than images received from the processor 51 and may provide the information to a user. The output module 56 may include, for example, a sound module such as a speaker, a haptic module such as a vibrating motor, and/or a light-emitting module such as a light-emitting diode (LED). In addition, the output module 56 may include a unique functional module of the electronic device 1 such as a cooling module of a refrigerator.

For example, the display module 11 may also be in charge of an output function. As an example, the display panel 10 included in the display module 11 may display (e.g., output) information processed by the electronic device 1. As an example, the display panel 10 may display execution screen information of an application driven by the electronic device 1, a user interface (UI), or graphic user interface (GUI) information corresponding to the execution screen information. The display panel 10 may include a display layer and a touchscreen layer, wherein the display layer displays images, and the touchscreen layer senses a user's touch input such as a touch of a finger or a stylus/pen. Accordingly, the display panel 10 may serve as a portion of the input module 55 that provides an input interface between the electronic device 1 and a user, and simultaneously, serve as a portion of the output module 56 that provides an output interface between the electronic device 1 and a user.

The communication module 57 is a module responsible for transmission/reception of information between the electronic device 1 and an external apparatus, and may include a receiver and a transmitter. The communication module 57 may include various types of wireless communication modules such as a mobile communication module, a broadcasting reception module, a wireless Internet module, a short range communication module, a Wi-Fi module, and/or a Bluetooth module, or various types of wired communication modules.

The electronic device 1 shown in FIG. 1 is just an example. As an example, a display device not having a communication function might not include the communication module 57. In addition, in the case where the electronic device 1 includes a display device, at least one of elements of the electronic device 1 may be included in the display device. In addition, some of individual modules functionally included in one module may be included in the display device, and some other individual modules may be included in the electronic device 1 separately from the display device. As an example, the display device may include the display module 11, and the processor 51, the memory 52, and the power module 54 may be elements of the electronic device 1, rather than being the display device itself. Alternatively, the display device may include the display module 11 and the power module 54, and the power module 54 may supply power to the elements such as the processor 51 and the memory 52 of the electronic device 1. However, various modifications may be made.

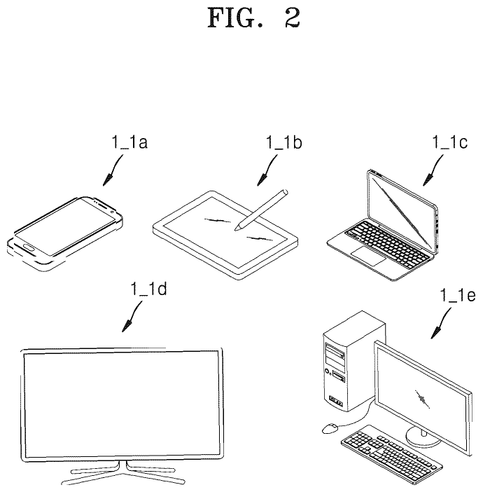

FIG. 2 is a schematic view of the electronic device 1 according to embodiments of the present invention. FIG. 2 shows, as an example of the electronic device 1, a smartphone 1_1a, a tablet computer 1_1b, a laptop/notebook computer 1_1c, and a television (TV) 1_1d, and a computer monitor 1_1e. The electronic device 1 may comprise a display panel, and a lower cover forming an exterior of the electronic device 1, the lower cover including an opening exposing a portion of the display panel.

The smartphone 1_1a may include not only the processor 51, the memory 52, the power module 54, and the display module 11, but also the input module 55 such as a touch sensor, and the communication module 57. The smartphone 1_1a may process information received through the communication module 57 or other input modules and display the information through the display module 11.

Similar to the smartphone 1_1a, the tablet computer 1_1b, the laptop/notebook computer 1_1c, the television (TV) 1_1d, and/or the computer monitor 1_1e may include the display module 11 and the input module 55 and may include the communication module 57, depending on the case.

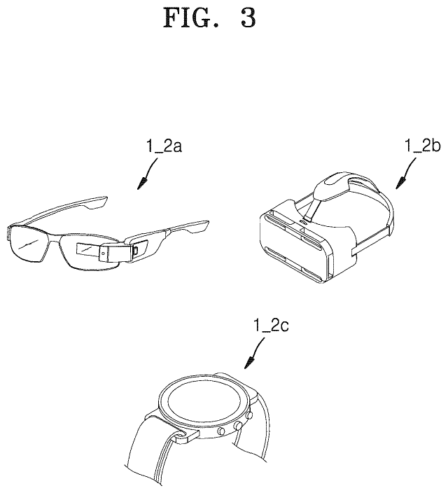

FIG. 3 is a schematic view showing a case where the electronic device 1 according to embodiments of the present invention is a wearable electronic device. FIG. 3 shows, as an example of the electronic device 1, smart glasses 1_2a, a head mount display 1_2b, and a smartwatch 1_2c.

The smart glasses 1_2a and the head mount display 1_2b may include the display module 11 displaying images and a reflector reflecting the images and providing the images to a user's eyes. A user may experience virtual reality or augmented reality using the electronic device 1.

The smartwatch 1_2c may include a biometric sensor as the input module 55 and provide, through the display module 11, a user with biometric information recognized through the biometric sensor.

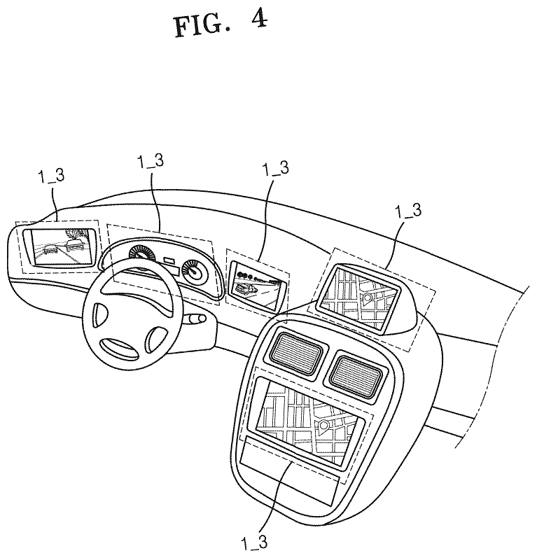

FIG. 4 is a schematic view showing a case where the electronic device 1 according to embodiments of the present invention is a vehicle electronic device 1_3. As shown in FIG. 4, the vehicle electronic device 1_3 may be included in an instrument board, a center facia or the like of an automobile, or may be a center information display (CID) disposed on a dashboard of an automobile or a room mirror display replacing a side mirror.

However, the electronic device 1, according to the present invention, is not necessarily limited thereto. As an example, the electronic device 1, according to an embodiment of the present invention, may include not only devices centered on displays such as digital billboards, electronic signboards, and/or portable game consoles, but also various home appliances that display information through a display module 11, such as a refrigerator, a washing machine, a dryer, an air conditioner, and/or a robot vacuum cleaner. In addition, in the case where the display module 11 has a function of transmitting light, the electronic device 1 may be a smart window or a transparent display device displaying a background and display images together. However, the electronic device 1, according to the present invention, is not necessarily limited thereto. As long as the electronic device 1 includes the display panel 10 described below, any electronic device may fall within the scope of the present invention.

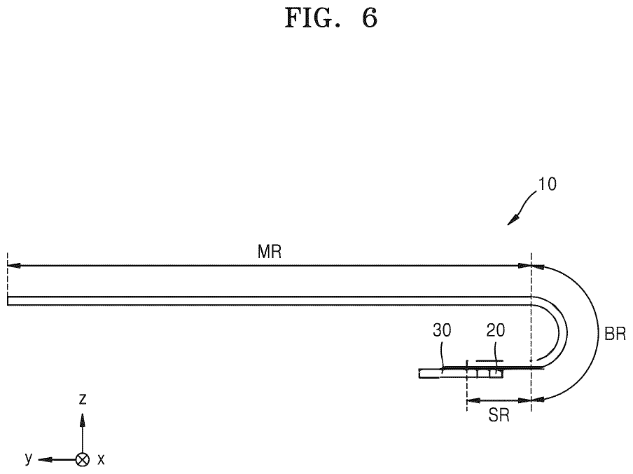

FIG. 5 is a schematic plan view of the display module 11 including the display panel 10 according to an embodiment of the present invention, and FIG. 6 is a schematic side view of the display module 11 of FIG. 5. The electronic device 1 may include the display module 11 shown in FIGS. 5 and 6.

The display panel 10 may include a display area DA and a peripheral area PA beyond the display area DA. The display area DA is a region in which images are displayed and a plurality of pixels may be disposed. The display area DA may have various shapes, for example, circular shapes, elliptical shapes, polygonal shapes, or shapes of specific figures. It is shown in FIG. 5 that the display area DA has a roughly rectangular shape having round corners.

The peripheral area PA may be disposed beyond the display area DA. The peripheral area PA may include a first peripheral area PA1 and a second peripheral area PA2, wherein the first peripheral area PA1 surrounds at least a portion of the display area DA, and the second peripheral area PA2 is disposed at the lower end of the display area DA and extends in a first direction (e.g., an x axis direction). The width of the second peripheral area PA2 in the first direction (e.g., the x axis direction) may be less than the width of the display area DA. At least a portion of the second peripheral area PA2 may be easily bendable to a noticeable extent without cracking or otherwise sustaining damage.

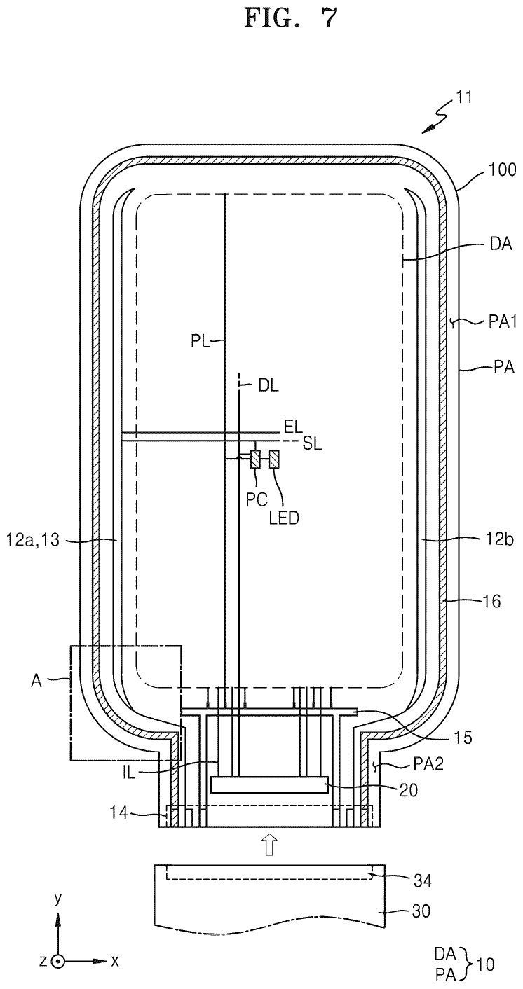

A planar shape of the display panel 10 shown in FIG. 5 may be substantially equal to the shape of a substrate 100 (see FIG. 7) included in the display panel 10. When the display panel 10 includes the display area DA and the peripheral area PA outside the display area DA, it may represent the substrate 100 includes the display area DA and the peripheral area PA outside the display area DA. Hereinafter, for convenience, description is made on the assumption that the substrate 100 includes the display area DA and the peripheral area PA.

The display panel 10 may include a main region MR, a bent region BR beyond the main region MR, and a sub-region SR spaced apart from the main region MR with the bent region BR interposed therebetween. The main region MR may be disposed at one side of the bent region BR, and the sub-region SR may be disposed at the other (e.g., opposite) side of the bent region BR. As shown in FIG. 6, the display panel 10 may be bent in the bent region BR, and when viewed from a third direction (e.g., a z axis direction), at least portion of the sub-region SR may overlap the main region MR.

Although it is shown in FIG. 6 that the display panel 10 is bent, the present invention is not necessarily limited thereto. As an example, the display panel 10 may be a foldable display panel, and in this case, the display panel 10 may be bent inside the display area DA around a bending axis crossing the display area DA. When needed, the display panel 10 might not be bent. The sub-region SR may be a non-display area.

The data driver 20 may be disposed in the sub-region SR of the display panel 10 included in the display module 11. The data driver 20 may be disposed on the display panel 10 in the form of an integrated circuit (IC). As an example, the data driver 20 may be a data driving integrated circuit generating data signals.

A display circuit board 30 may be attached to the end of the sub-region SR of the display panel 10. For example, when needed, the display module 11 may include the display circuit board 30. The display circuit board 30 may be electrically connected to the data driver 20 or the like through a pad of the sub-region SR of the display panel 10.

FIG. 7 is a schematic plan view of the display module 11 of FIG. 5. As shown in FIG. 7, the display panel 10 included in the display module 11 may include the substrate 100. Various elements forming the display panel 10 may be disposed on the substrate 100.

The substrate 100 may include glass, ceramic, metal, or polymer resin. The substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers including the above-described polymer resin, and an inorganic material layer interposed therebetween. Alternatively, the substrate 100 may have a structure in which a layer including the polymer resin and an inorganic material layer are alternately stacked. The inorganic material layer may include, for example, silicon oxide, silicon nitride, or silicon oxynitride.

The pixels may be located in the display area DA, and the display area DA may display images using light emitted from the pixels. Each pixel may include a light-emitting diode LED, and the light-emitting diode LED may be electrically connected to a pixel circuit PC. The pixel circuit PC and the light-emitting diode LED may be disposed in the display area DA. For convenience, although it is shown in FIG. 7 that the pixel circuit PC and the light-emitting diode LED are disposed side-by-side, the pixel circuit PC may at least partially overlap the light-emitting diode LED. As an example, the light-emitting diode LED may be disposed on the pixel circuit PC.

A gate driving circuit, a pad 14, a first power supply line 15, and a second power supply line 16 may be disposed in the peripheral area PA. The gate driving circuit may include, for example, a first scan driving circuit 12a, a second scan driving circuit 12b, and/or an emission control driving circuit 13.

The first scan driving circuit 12a may be configured to provide scan signals to the pixel circuit PC through a gate line SL. The second scan driving circuit 12b may be arranged opposite to the first scan driving circuit 12a with the display area DA interposed therebetween. Some of the pixel circuits PC disposed in the display area DA may be electrically connected to the first scan driving circuit 12a, and the others may be connected to the second scan driving circuit 12b. Depending on the case, the second scan driving circuit 12b may be omitted.

Like the first scan driving circuit 12a, the emission control driving circuit 13 may be disposed at one side of the display area DA. The emission control driving circuit 13 may provide emission control signals to a pixel P through an emission control line EL. Although it is shown in FIG. 7 that the emission control driving circuit 13 is disposed at only one side of the display area DA, the present invention is not necessarily limited thereto. For example, the display panel 10 may include the emission control driving circuits 13 disposed at one side and another side of the display area DA. Alternatively, the display panel 10 may include the first scan driving circuit 12a disposed at one side of the display area DA, and the emission control driving circuit 13 disposed at the other side of the display area DA.

The pad 14 may be disposed in the second peripheral area PA2 of the substrate 100. The pad 14 may be exposed by virtue of not being covered by an insulating layer, and may be electrically connected to the display circuit board 30. A pad 34 of the display circuit board 30 may be electrically connected to the pad 14 of the display panel 10.

The display circuit board 30 is configured to transfer signals or power of a controller to the display panel 10. Control signals generated by the controller may be transferred to the gate driving circuit through the display circuit board 30. In addition, the controller may provide a first power voltage ELVDD and a second power voltage ELVSS to the first power supply line 15 and the second power supply line 16. The first power voltage ELVDD (referred to as a driving voltage, hereinafter) may be provided to each pixel circuit PC through a driving voltage line PL connected to the first power supply line 15, and the second power voltage ELVSS (referred to as a common voltage, hereinafter) may be provided to a common electrode of the light-emitting diode LED connected to the second power supply line 16. The first power supply line 15 may extend in the first direction (e.g., the x axis direction). The second power supply line 16 may have a loop shape having one open side and partially surround the display area DA.

Data signals of the data driver 20 may be transferred to the pixel circuit PC through the data line DL electrically connected to an input line IL through the input line IL.

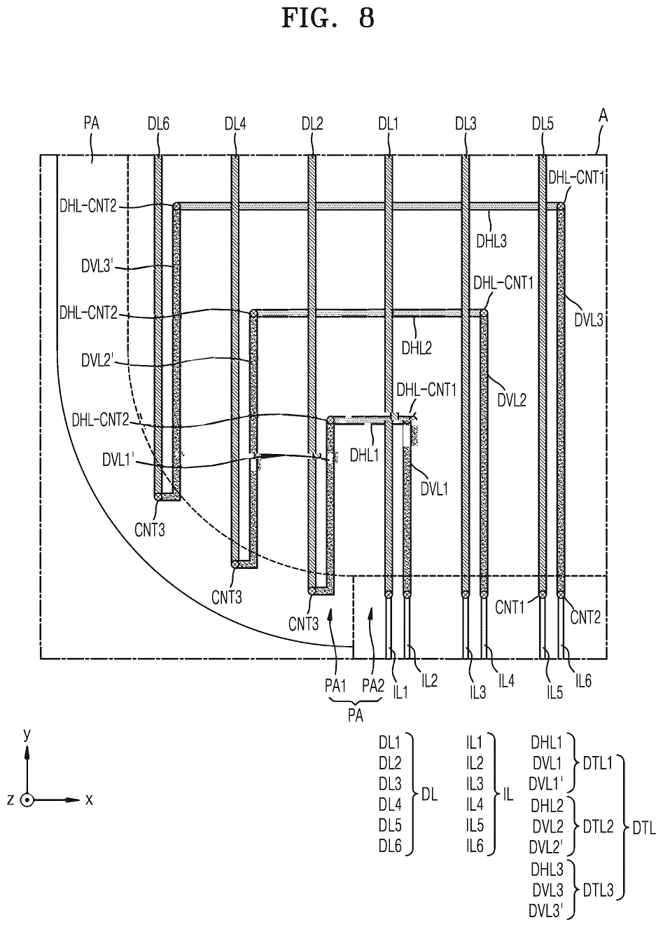

FIG. 8 is a schematic enlarged conceptual view of a region A of the display module 11 of FIG. 7. As shown in FIG. 8, the data line DL extending in a second direction (a y axis direction) is disposed in the display area DA, and the input line IL is located in the peripheral area PA. The input line IL may transfer data signals of the data driver 20 to the data line DL. For convenience of illustration, although FIG. 8 shows that the data line DL includes a first data line DL1, a second data line DL2, a third data line DL3, a fourth data line DLA, a fifth data line DL5, and a sixth data line DL6, and the input line IL includes a first input line IL1, a second input line IL2, a third input line IL3, a fourth input line IL4, a fifth input line IL5, and a sixth input line IL6, the number of the data lines DL and the number of the input lines IL may be variously changed.

Some of the data lines DL may be directly connected to a corresponding input line IL, but some other data lines DL may be electrically connected to a corresponding input line IL through a data transfer line DTL.

The first data line DL1, the third data line DL3, and the fifth data line DL5 may receive data signals from the first input line IL1, the third input line IL3, and the fifth input line IL5. The first data line DL1, the third data line DL3, and the fifth data line DL5 may be electrically connected to the first input line IL1, the third input line IL3, and the fifth input line IL5. Each of the first data line DL1, the third data line DL3, and the fifth data line DL5 may be integrally formed with a corresponding one of the first input line IL1, the third input line IL3, and the fifth input line IL5. Alternatively, each of the first data line DL1, the third data line DL3, and the fifth data line DL5 may be electrically connected to a corresponding one of the first input line IL1, the third input line IL3, and the fifth input line IL5 through a first contact hole CNT1, as shown in FIG. 8.

The second data line DL2, the fourth data line DLA, and the sixth data line DL6 may be electrically connected to the second input line IL2, the fourth input line IL4, and the sixth input line IL6 through a first data transfer line DTL1, a second data transfer line DTL2, and a third data transfer line DTL3. For example, the second input line IL2 may be electrically connected to the second data line DL2 through the first data transfer line DTL1, the fourth input line IL4 may be electrically connected to the fourth data line DLA through the second data transfer line DTL2, and the sixth input line IL6 may be electrically connected to the sixth data line DL6 through the third data transfer line DTL3.

Most of each of the first data transfer line DTL1, the second data transfer line DTL2, and the third data transfer line DTL3 may be located within the display area DA. One end of each of the first data transfer line DTL1, the second data transfer line DTL2, and the third data transfer line DTL3 may be electrically connected to a corresponding one of the second input line IL2, the fourth input line IL4, and the sixth input line IL6 through a second contact hole CNT2. Another end of each of the first data transfer line DTL1, the second data transfer line DTL2, and the third data transfer line DTL3 may be electrically connected to a corresponding one of the second data line DL2, the fourth data line DL4, and the sixth data line DL6 through a third contact hole CNT3. For example, although it is shown in FIG. 8 that the second contact hole CNT2 and the third contact hole CNT3 are located in the peripheral area PA, the present invention is not necessarily limited thereto. As an example, the second contact hole CNT2 and/or the third contact hole CNT3 may be located in the display area DA.

The first data transfer line DTL1 may include a first horizontal connection line DHL1, a first vertical connection line DVL1, and a first additional vertical connection line DVL1′, the second data transfer line DTL2 may include a second horizontal connection line DHL2, a second vertical connection line DVL2, and a second additional vertical connection line DVL2′, and the third data transfer line DTL3 may include a third horizontal connection line DHL3, a third vertical connection line DVL3, and a third additional vertical connection line DVL3′. The first horizontal connecting line DHL1, the second horizontal connecting line DHL2, and the third horizontal connecting line DHL3 may extend approximately in the first direction (e.g., the x axis direction). The first vertical connection line DVL1, the second vertical connection line DVL2, the third vertical connection line DVL3, the first additional vertical connection line DVL1′, the second additional vertical connection line DVL2′, and the third additional vertical connection line DVL3′ may extend approximately in the second direction (e.g., the y axis direction) and may be substantially parallel to the data line DL.

Each of the second input line IL2, the fourth input line IL4, and the sixth input line IL6 may be electrically connected to a corresponding one of the first vertical connection line DVL1, the second vertical connection line DVL2, and the third vertical connection line DVL3 through the second contact hole CNT2, and each of the second data line DL2, the fourth data line DLA, and the sixth data line DL6 may be electrically connected to a corresponding one of the first additional vertical connection line DVL1′, the second additional vertical connection line DVL2′, and the third additional vertical connection line DVL3′ through the third contact hole CNT3. Each of the first horizontal connecting line DHL1, the second horizontal connecting line DHL2, and the third horizontal connecting line DHL3 may be electrically connected to a corresponding one of the first vertical connecting line DVL1, the second vertical connecting line DVL2, and the third vertical connecting line DVL3 through a first connecting contact hole DHL-CNT1, and may be electrically connected to a corresponding one of the first additional vertical connecting line DVL1′, the second additional vertical connecting line DVL2′, and the third additional vertical connecting line DVL3′ through a second connecting contact hole DHL-CNT2.

The first vertical connecting line DVL1, the second vertical connecting line DVL2, the third vertical connecting line DVL3, the first additional vertical connecting line DVL1′, the second additional vertical connecting line DVL2′, and the third additional vertical connecting line DVL3′ may be disposed on the same first layer, and the first horizontal connecting line DHL1, the second horizontal connecting line DHL2, and the third horizontal connecting line DHL3 may be disposed on a second layer that is different from the first layer. For example, when certain components are disposed on the same layer, those components may be formed simultaneously using the same material through the same mask process.

As described above, FIG. 8 shows that the first data transfer line DTL1 includes a first horizontal connection line DHL1, a first vertical connection line DVL1, and a first additional vertical connection line DVL1′, the second data transfer line DTL2 includes a second horizontal connection line DHL2, a second vertical connection line DVL2, and a second additional vertical connection line DVL2′, and the third data transfer line DTL3 includes a third horizontal connection line DHL3, a third vertical connection line DVL3, and a third additional vertical connection line DVL3′. However, the present invention is not necessarily limited thereto.

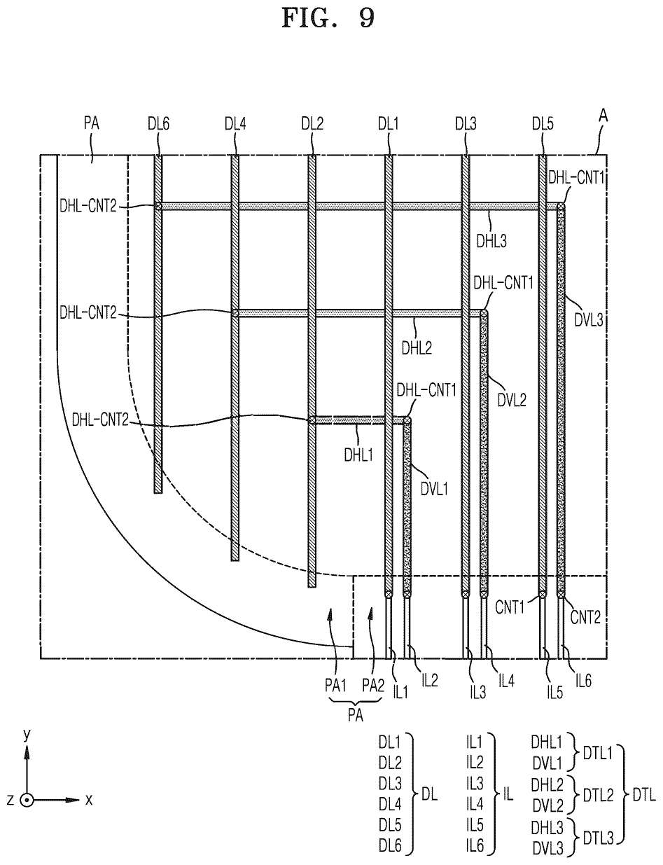

As an example, as shown in FIG. 9, which is a schematic enlarged conceptual diagram of a portion of the display panel 10 according to an embodiment of the present invention, a first data transfer line DTL1 may include a first horizontal connection line DHL1 and a first vertical connection line DVL1, a second data transfer line DTL2 may include a second horizontal connection line DHL2 and a second vertical connection line DVL2, and a third data transfer line DTL3 may include a third horizontal connection line DHL3 and a third vertical connection line DVL3. In this case, each of the first horizontal connection line DHL1, the second horizontal connection line DHL2, and the third horizontal connection line DHL3 may be electrically connected to a corresponding one of the first vertical connection line DVL1, the second vertical connection line DVL2, and the third vertical connection line DVL3 through the first connection contact hole DHL-CNT1, and may be electrically connected to a corresponding one of the second data line DL2, the fourth data line DL4, and the sixth data line DL6 through the second connection contact hole DHL-CNT2.

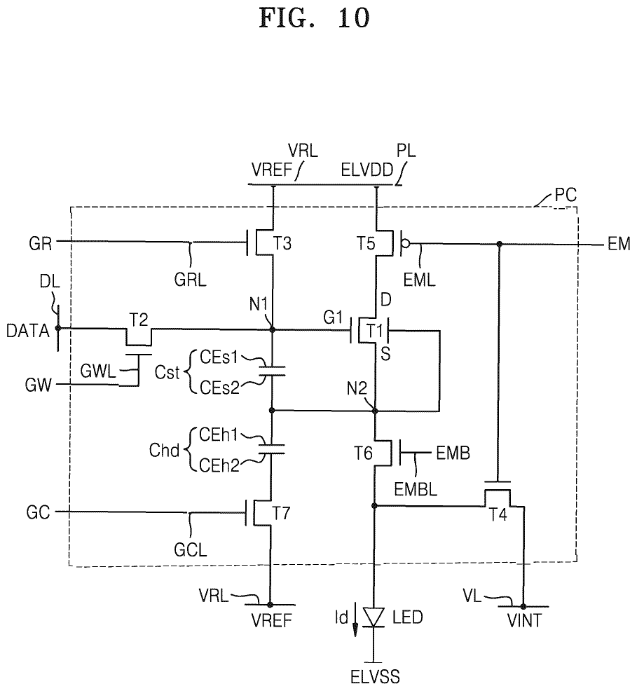

FIG. 10 is an equivalent circuit diagram of a pixel located in a display area DA of the display panel 10 included in the display module 11 of FIG. 7. As shown in FIG. 10, the pixel circuit PC connected to the light-emitting diode LED may include a plurality of transistors and a plurality of capacitors. As an example, the pixel circuit PC may include a first transistor T1, a second transistor T2, a third transistor T3, a fourth transistor T4, a fifth transistor T5, a sixth transistor T6, a seventh transistor T7, a storage capacitor Cst, and a hold capacitor Chd.

The first transistor T1 may be a driving transistor outputting a driving current corresponding to a data signal, and the second transistor T2, the third transistor T3, the fourth transistor T4, the fifth transistor T5, the sixth transistor T6, and the seventh transistor T7 may be switching transistors transferring signals through on/off operations. A first terminal (a first electrode) of each of the first transistor T1, the second transistor T2, the third transistor T3, the fourth transistor T4, the fifth transistor T5, the sixth transistor T6, and the seventh transistor T7 may be one of a source region and a drain region, and a second terminal (a second electrode) may be the other.

At least one of the first transistor T1, the second transistor T2, the third transistor T3, the fourth transistor T4, the fifth transistor T5, the sixth transistor T6, and the seventh transistor T7 may be a p-channel metal oxide semiconductor field effect transistor (PMOS), and the rest of the transistors may be n-channel metal oxide semiconductor field effect transistors (NMOSs). As an example, the fifth transistor T5 may be a PMOS, and the first transistor T1, the second transistor T2, the third transistor T3, the fourth transistor T4, the sixth transistor T6, and the seventh transistor T7 may be NMOSs. Alternatively, the fifth transistor T5 and the sixth transistor T6 may be PMOSs, and the first transistor T1, the second transistor T2, the third transistor T3, the fourth transistor T4, and the seventh transistor T7 may be NMOSs. Alternatively, all the transistors may be NMOSs or all the transistors may be PMOSs.

At least one of the transistors may be a transistor having a low-temperature polycrystalline silicon (LTPS) semiconductor layer, and the remaining transistors may be transistors having an oxide semiconductor layer. As used herein, LTPS semiconductor layers may be a specialized form of silicon used to create thin-film transistors for high-performance display panels. Unlike amorphous silicon, which lacks a crystalline structure, LTPS is composed of many small silicon crystals that allow for significantly better electrical conductivity. LTPS may be manufactured using processes such as laser annealing to crystallize silicon at relatively low temperatures. The resulting LTPS semiconductor layer may exhibit high electron mobility, meaning that electric charges move through it quickly and efficiently. This characteristic enables the production of transistors that can switch pixels on and off more rapidly, making LTPS ideal for high-resolution, high-refresh-rate displays found in modern smartphones, tablets, and advanced monitors. Because the transistors can be made smaller and more efficient, LTPS technology also contributes to lower power consumption and allows complex circuitry to be integrated directly onto the display itself.

As an example, the fifth transistor T5 may include a semiconductor layer including polycrystalline silicon having high reliability, and each of the remaining transistors may include an oxide semiconductor layer having characteristics of high carrier mobility and low leakage current. Hereinafter, a case where the fifth transistor T5 is a PMOS including a silicon semiconductor layer, and the remaining transistors are NMOSs including an oxide semiconductor layer is described.

The pixel circuit PC may be electrically connected to gate lines transferring signals to a gate electrode of each of the transistors. As an example, the pixel circuit PC may be connected to a scan line GWL transferring a scan signal GW, a first reference gate line GRL transferring a first reference signal GR, a second reference gate line GCL transferring a second reference signal GC, a first emission control line EML transferring a first emission control signal EM, a second emission control line EMBL transferring a second emission control signal EMB, and a data line DL transferring a data signal DATA. In addition, the pixel circuit PC may be connected to the driving voltage line PL transferring a driving voltage ELVDD, a reference voltage line VRL transferring a reference voltage VREF, and an initialization voltage line VL transferring an initialization voltage VINT.

The first transistor T1, which is a driving transistor, may be electrically connected between the driving voltage line PL and a second node N2. The first transistor T1 may include a first gate electrode G1 connected to a first node N1, a first terminal electrically connected to the driving voltage line PL, and a second terminal connected to the second node N2. The first terminal may be a drain region D, and the second terminal may be a source region S. The first terminal of the first transistor T1 may be electrically connected to the driving voltage line PL through the fifth transistor T5, and the second terminal of the first transistor T1 may be electrically connected to a pixel electrode of a light-emitting diode LED through the sixth transistor T6. The first transistor T1 may receive a data signal DATA according to a switching operation of the second transistor T2 and be configured to control the amount of driving current Id flowing through the light-emitting diode LED.

The second transistor T2, which is a data-write transistor, may be electrically connected between the data line DL and the first node N1. The second transistor T2 may include a gate electrode, a first terminal, and a second terminal, wherein the gate electrode is connected to the scan line GWL, the first terminal is connected to the data line DL, and the second terminal is connected to the first node N1. The second transistor T2 may be turned on according to a scan signal GW transferred to the scan line GWL to electrically connect the data line DL to the first node N1 and transfer a data signal DATA to the first node N1, the data signal DATA being transferred from the data line DL.

The third transistor T3, which is a first initialization transistor, may be electrically connected between the first node N1 and the reference voltage line VRL. The third transistor T3 may include a gate electrode, a first terminal, and a second terminal, wherein the gate electrode is connected to the first reference gate line GRL, the first terminal is connected to the first node N1, and the second terminal is connected to the reference voltage line VRL. The third transistor T3 may be turned on according to a first reference signal GR transferred to the first reference gate line GRL and may transfer the reference voltage VREF to the first node N1, the reference voltage VREF being from the reference voltage line VRL.

The fourth transistor T4, which is a second initialization transistor, may be electrically connected between the first transistor T1 and the initialization voltage line VL. For example, the fourth transistor T4 may be electrically connected between the sixth transistor T6 and the initialization voltage line VL. The fourth transistor T4 may include a gate electrode, a first terminal, and a second terminal, wherein the gate electrode is connected to the first emission control line EML, the first terminal is connected to the second terminal of the sixth transistor T6 and the light-emitting diode LED, and the second terminal is connected to the initialization voltage line VL. The fourth transistor T4 may be turned on according to a first emission control signal EM transferred to the first emission control line EML and may transfer the initialization voltage VINT to the pixel electrode of the light-emitting diode LED, the initialization voltage VINT being from the initialization voltage line VL. For example, the fourth transistor T4 may initialize the potential of the pixel electrode of the light-emitting diode LED to the initialization voltage VINT.

The fifth transistor T5, which is an emission control transistor, may be electrically connected between the driving voltage line PL and the first transistor T1. The fifth transistor T5 may include a gate electrode, a first terminal, and a second terminal, wherein the gate electrode is connected to the first emission control line EML, the first terminal is connected to the driving voltage line PL, and the second terminal is connected to the first terminal of the first transistor T1. The fifth transistor T5 may be turned on or turned off according to a first emission control signal EM from the first emission control line EML.

The sixth transistor T6, which is an operation control transistor, may be connected between the first transistor T1 and the light-emitting diode LED. The sixth transistor T6 may include a gate electrode, a first terminal, and a second terminal, wherein the gate electrode is connected to the second emission control line EMBL, the first terminal is connected to the second node N2, and the second terminal is connected to the light-emitting diode LED. The sixth transistor T6 may be turned on according to a second emission control signal EMB from the second emission control line EMBL and may electrically connect the second node N2 to the pixel electrode of the light-emitting diode LED.

For example, although it is shown in FIG. 10 that the fifth transistor T5 operates in response to a first emission control signal EM, and the sixth transistor T6 operates in response to a second emission control signal EMB, the present invention is not necessarily limited thereto. As an example, the fifth transistor T5 and the sixth transistor T6 may operate in response to the same emission control signal.

For example, a first reference signal GR may be substantially synchronized with a scan signal GW of the pixel circuit PC located in a previous row. A second reference signal GC described below may also be substantially synchronized with a scan signal GW of the pixel circuit PC located in the previous row, or be substantially synchronized with a scan signal GW or a first reference signal GR of the pixel circuit PC located in the next row.

The storage capacitor Cst may be electrically connected between the first node N1 and the second node N2. For example, the pixel circuit PC included in the display panel according to the present embodiment may be a source-follower type circuit in which the storage capacitor Cst is connected between the first node N1 and the second node N2. A first storage electrode CEs1 of the storage capacitor Cst may be connected to the first node N1, and a second storage electrode CEs2 may be connected to the second node N2. The electrodes that constitute the capacitor can be referred to as capacitor electrodes. The storage capacitor Cst may store a threshold voltage of the first transistor T1 and a voltage corresponding to a data signal DATA. As used herein, a source-follower type circuit may be a configuration in which the input signal is applied to the gate and the output is taken from the source terminal. In this setup, the voltage at the source closely follows the voltage at the gate, typically reduced by a small amount due to the transistor's threshold voltage. Although it does not amplify the voltage, the circuit serves as a buffer, maintaining signal strength while allowing it to drive lower-impedance components. This makes it especially useful in display technologies, where it helps stabilize the voltage delivered to pixel elements, ensuring consistent image quality.

The hold capacitor Chd may be connected between the seventh transistor T7 and the second node N2. A first hold electrode CEh1 of the hold capacitor Chd may be electrically connected to the second node N2, and a second hold electrode CEh2 may be electrically connected to the reference voltage line VRL through the seventh transistor T7. The hold capacitor Chd may ensure that a voltage of the second node N2 of the first transistor T1 does not fluctuate and is constant when a surrounding signal fluctuates.

The seventh transistor T7, which is a third initialization transistor, may be connected between the second hold electrode CEh2 of the hold capacitor Chd and the reference voltage line VRL. The seventh transistor T7 may include a gate electrode, a first terminal, and a second terminal, wherein the gate electrode is connected to the second reference gate line GCL, the first terminal is connected to the second hold electrode CEh2 of the hold capacitor Chd, and the second terminal is connected to the reference voltage line VRL. The seventh transistor T7 may be turned on according to a second reference signal GC transferred to the second reference gate line GCL and may transfer the reference voltage VREF to the second hold electrode CEh2 of the hold capacitor Chd, the reference voltage VREF being from the reference voltage line VRL.

The light-emitting diode LED may include the pixel electrode and a common electrode over the pixel electrode, wherein the pixel electrode is electrically connected to the second node N2 through the sixth transistor T6, and the common electrode may receive the common voltage ELVSS. The common electrode may be an integral body over a plurality of light-emitting diodes LED. As used herein, the term “integral body” may be intended to indicate a single uninterrupted structure that is not comprised of individual parts.

Although it is shown in FIG. 10 that the pixel circuit PC includes seven transistors and two capacitors, the present invention is not necessarily limited thereto. As an example, the pixel circuit PC may include five transistors and two capacitors. The pixel circuit PC may include six transistors and one or two capacitors.

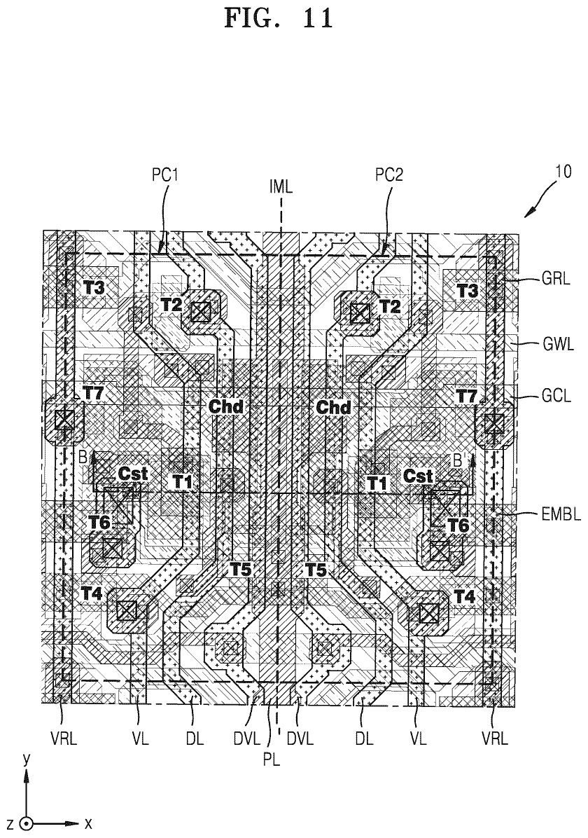

FIG. 11 is a schematic arrangement view showing the positions of transistors and a capacitor and the like in pixels located in the display area of the display panel 10 included in the display module 11. For convenience of description, FIG. 11 shows two pixel circuits, for example, a first pixel circuit PC1 and a second pixel circuit PC2 located in the same row in the first direction (e.g., the x axis direction). However, the present invention is not necessarily limited thereto. In addition, although it is shown in FIG. 11 that the first pixel circuit PC1 and the second pixel circuit PC2 are approximately mirror-symmetrical with respect to each other about an imaginary line IML extending in the second direction (e.g., the y axis direction), the present invention is not necessarily limited thereto. The display panel 10 may include a plurality of pixel circuits arranged to form a row in the first direction (e.g., the x axis direction) and a column in the second direction (e.g., the y axis direction).

As shown in FIG. 11, each of the first pixel circuit PC1 and the second pixel circuit PC2 may include transistors and capacitors. As an example, each of the first pixel circuit PC1 and the second pixel circuit PC2 may include the first to seventh transistors T1 to T7, the storage capacitor Cst, and the hold capacitor Chd described above with reference to FIG. 10. For example, when taking into account the first pixel circuit PC1 and the second pixel circuit PC2, two first transistors T1 may be arranged adjacent to each other in the first direction (e.g., the x axis direction).

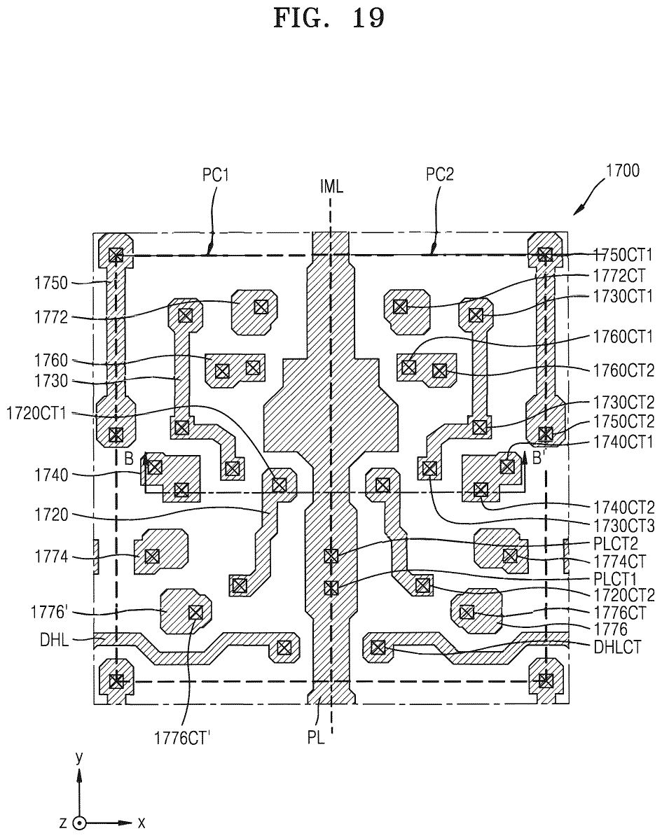

The gate lines electrically connected to the first pixel circuit PC1 and the second pixel circuit PC2, for example, the scan line GWL, the first reference gate line GRL, the second reference gate line GCL, the first emission control line EML, and the second emission control line EMBL may extend substantially in the first direction (e.g., the x axis direction). Besides, a horizontal connection line DHL (see FIG. 19) may also extend substantially in the first direction (e.g., the x axis direction).

The first pixel circuit PC1 may be electrically connected to the data line DL passing by the first pixel circuit PC1, and the second pixel circuit PC2 may be electrically connected to the data line DL passing by the second pixel circuit PC2. The data line DL may extend substantially in the second direction (e.g., the y direction). The data line DL electrically connected to the first pixel circuit PC1 and the data line DL electrically connected to the second pixel circuit PC2 may be symmetrical to each other with respect to the imaginary line IML described above.

The first pixel circuit PC1 may be electrically connected to a voltage line, for example, the reference voltage line VRL and the initialization voltage line VL passing by the first pixel circuit PC1. The second pixel circuit PC2 may be electrically connected to a voltage line, for example, the reference voltage line VRL and the initialization voltage line VL passing by the second pixel circuit PC2. The reference voltage line VRL and the initialization voltage line VL electrically connected to the first pixel circuit PC1 and the reference voltage line VRL and the initialization voltage line VL electrically connected to the second pixel circuit PC2 may be symmetrical to each other with respect to the imaginary line IML described above. Each of the reference voltage line VRL and the initialization voltage line VL may extend substantially in the second direction (e.g., the y axis direction). For convenience, the initialization voltage line VL passing by the first pixel circuit PC1 may be referred to as a first initialization voltage line, and the initialization voltage line VL passing by the second pixel circuit PC2 may be referred to as a second initialization voltage line. For example, first initialization voltage lines and second initialization voltage lines extending in the second direction (e.g., the y axis direction) may be alternately arranged in the first direction (e.g., the x axis direction).

A vertical connection line DVL may also extend in the second direction (e.g., the y axis direction). The vertical connection line DVL may correspond to a portion of the data transfer line DTL described with reference to FIG. 8 or 9, for example, one of the first vertical connection line DVL1, the second vertical connection line DVL2, the third vertical connection line DVL3, the first additional vertical connection line DVL1′, the second additional vertical connection line DVL2′, and the third additional vertical connection line DVL3′. In this case, the vertical connection line DVL may be electrically connected to a data line DL of a pixel circuit located in a different column from the first pixel circuit PC1 and the second pixel circuit PC2 shown in FIG. 11 to transfer data signals to pixel circuits in the different column. Alternatively, in the case where the first pixel circuit PC1 or the second pixel circuit PC2 is not located near the corner of the display area DA as shown in FIG. 8 or 9 but is located in the center of the display area DA, the vertical connection line DVL may be a dummy line to which an electrical signal is not applied, or a dummy line to which a preset electrical signal is applied when needed.

For example, a horizontal connection line DHL described below may correspond to a portion of the data transfer line DTL described with reference to FIG. 8 or 9, for example, one of the first horizontal connection line DHL1, the second horizontal connection line DHL2, and the third horizontal connection line DHL3. In this case, the horizontal connection line DHL, together with the vertical connection line DVL, may be electrically connected to a data line DL of a pixel circuit located in a different column from the first pixel circuit PC1 and the second pixel circuit PC2 shown in FIG. 11 to transfer data signals to pixel circuits in the different column. Alternatively, in the case where the first pixel circuit PC1 or the second pixel circuit PC2 is not located near the corner of the display area DA as shown in FIG. 8 or 9 but is located in the center of the display area DA, the horizontal connection line DHL may be a dummy line to which an electrical signal is not applied, or a dummy line to which a preset electrical signal is applied when needed.

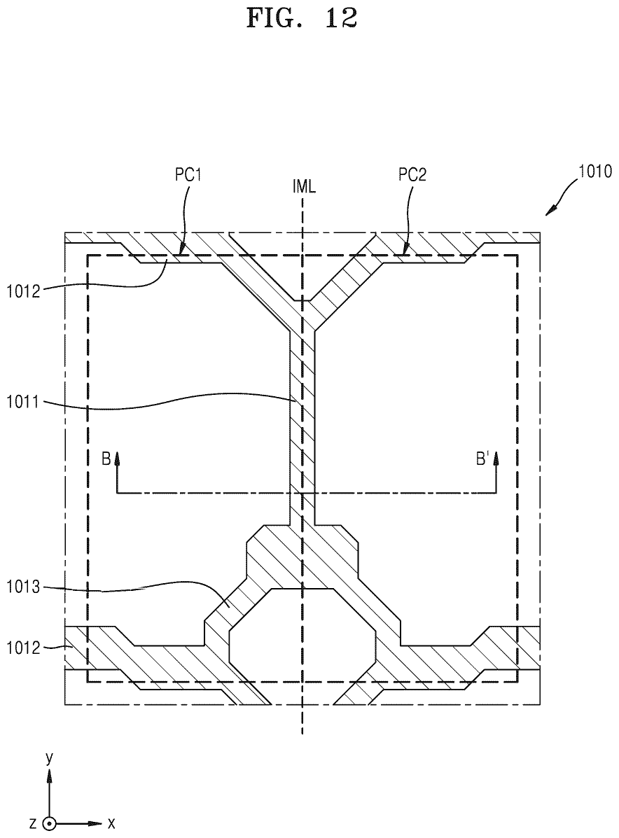

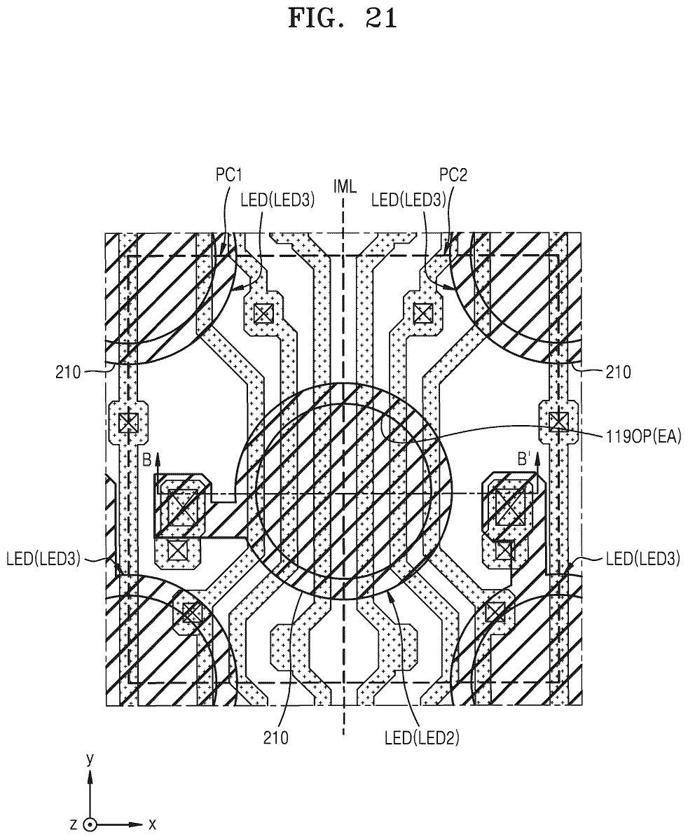

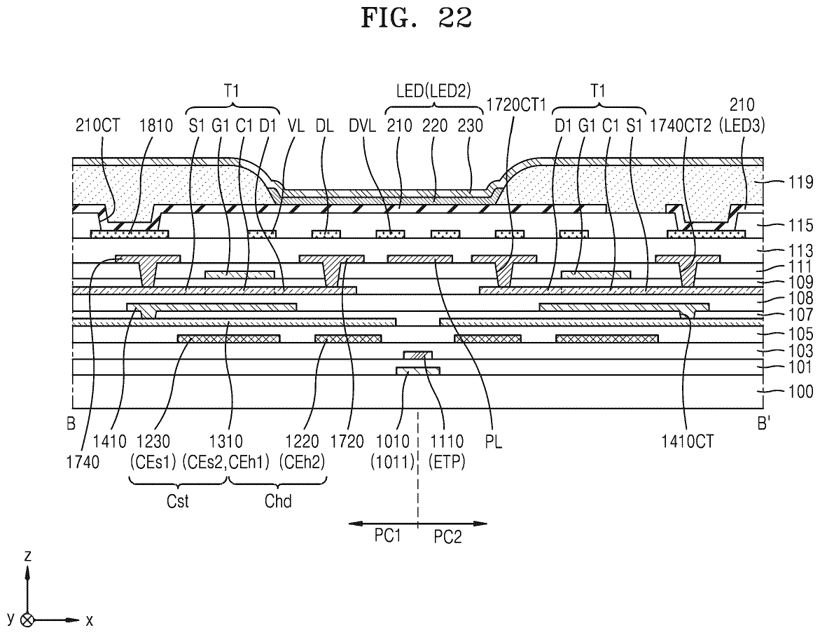

FIGS. 12 to 20 are schematic arrangement views of elements such as transistors and capacitors, for each layer, of the display panel 10 shown in FIG. 11. FIG. 21 is a schematic arrangement view of pixel electrodes of the display panel 10 of FIG. 11. In addition, FIG. 22 is a schematic cross-sectional view taken along line B-B′ of FIGS. 11 to 21.

For convenience of description, a case is described in which the first pixel circuit PC1 is located in an i-th row and a j-th column, and the second pixel circuit PC2 is located in an i-th row and a (j+1)-th column.

The display panel 10 may include a circuit layer including transistors and capacitors disposed on the substrate 100, and a display element layer disposed on the circuit layer and including the light-emitting diode LED. The circuit layer may include the transistors and the capacitors described with reference to FIGS. 10 and 11.

As shown in FIG. 12, a bottom metal layer 1010 may be disposed on the substrate 100. The bottom metal layer 1010 may include a first portion 1011, a second portion 1012, and a third portion 1013, wherein the first portion 1011 extends in the second direction (e.g., the y axis direction), and the second portion 1012 and the third portion 1013 extend in the first direction (e.g., the x axis direction).

The first portion 1011 may be located on the imaginary line IML between the first pixel circuit PC1 and the second pixel circuit PC2. The second portion 1012 and the third portion 1013 of the bottom metal layer 1010 may be located on opposite sides with the first portion 1011 interposed therebetween. The second portion 1012 and the third portion 1013 may entirely extend in the first direction (e.g., the x direction) and may be partially bent. The bottom metal layer 1010 may include a metal material. For example, the bottom metal layer 1010 may include at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). As an example, the bottom metal layer 1010 may have a single-layered structure including molybdenum, a double-layered structure in which a molybdenum layer and a titanium layer are stacked, or a triple-layered structure in which a titanium layer, an aluminum layer, and a titanium layer are stacked.

The bottom metal layer 1010 may have a constant voltage level. As an example, the bottom metal layer 1010 may have the same voltage as the driving voltage line PL described above with reference to FIG. 10. For example, the driving voltage ELVDD may be applied to the bottom metal layer 1010. For this purpose, the bottom metal layer 1010 may be electrically connected to a portion of the driving voltage line PL or the first power supply line 15, for example, in the peripheral area PA. The bottom metal layer 1010 may shield at least a portion of light progressing to a fifth semiconductor layer A5 of the fifth transistor T5 and protect the fifth transistor T5 from electrostatic discharge ESD.

A buffer layer 101 may be disposed on the bottom metal layer 1010 to cover the bottom metal layer 1010. The buffer layer 101 may be an inorganic insulating layer including an inorganic insulating material such as silicon oxide, silicon nitride, and/or silicon oxynitride. The buffer layer 101 may have a single-layered structure or a multi-layered structure.

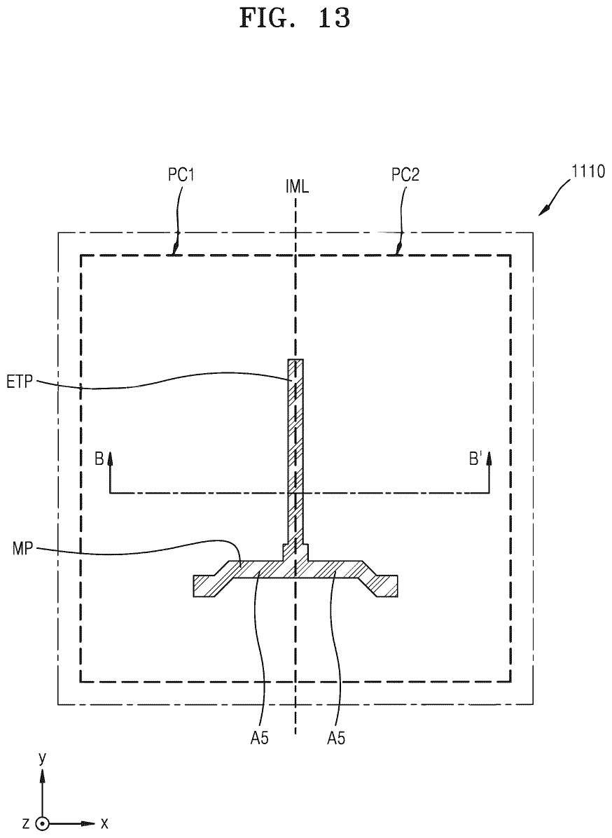

A silicon semiconductor layer 1110 shown in FIG. 13 may be disposed on the buffer layer 101. The silicon semiconductor layer 1110 may include silicon, for example, polycrystalline silicon.

As shown in FIG. 13, the silicon semiconductor layer 1110 may have an isolated shape. As used herein, the phrase “isolated shape” may mean that the structure is physically separated and not connected to similar structure that may be nearby or on the same layer. In addition, the silicon semiconductor layer 1110 may include a main portion MP having a shape extending substantially in the first direction (e.g., the x axis direction) and an extension portion ETP having a shape extending in a second direction (e.g., a y axis direction) crossing the first direction. The main portion MP and the extension portion ETP may be an integral body. The main portion MP of the silicon semiconductor layer 1110 may cross an imaginary line IML between the first pixel circuit PC1 and the second pixel circuit PC2. In addition, the extension portion ETP of the silicon semiconductor layer 1110 may overlap the imaginary line IML between the first pixel circuit PC1 and the second pixel circuit PC2 in a plan view. In a plan view, the extension portion ETP may be located between the first transistor T1 of the first pixel circuit PC1 and the second transistor T2 of the second pixel circuit PC2. The silicon semiconductor layer 1110 may include the fifth semiconductor layer A5 of each of the first pixel circuit PC1 and the second pixel circuit PC2. In other words, the fifth semiconductor layer A5 of the first pixel circuit PC1 and the fifth semiconductor layer A5 of the second pixel circuit PC2 may be an integral body.

When the silicon semiconductor layer 1110 has only the main portion MP and does not have the extension portion ETP, an area occupied by the silicon semiconductor layer 1110 in an area of a first pixel circuit PC1 and an area of a second pixel circuit PC2 becomes very small. In this case, during a process of forming a layer including a silicon semiconductor material on an approximate entire surface of a substrate 100 and patterning the layer using photoresist and the like to form the main portion MP, the amount of removed photoresist is large, and accordingly, a lot of time is consumed, and in addition, defects that the main portion MP is not formed in an intended shape may occur. In contrast, in the display panel 10, according to the present embodiment, and the electronic device 1 including the same, because the silicon semiconductor layer 1110 includes the extension portion ETP as well as the main portion MP, an area occupied by the silicon semiconductor layer 1110 in the area of the first pixel circuit PC1 and the area of the second pixel circuit PC2 may be increased. In addition, the occurrence of defects during the manufacturing process may be effectively prevented or minimized.

The silicon semiconductor layer 1110 may overlap the bottom metal layer 1010. As an example, the main portion MP of the silicon semiconductor layer 1110 may approximately overlap the third portion 1013 of the bottom metal layer 1010, and the extension portion ETP of the silicon semiconductor layer 1110 may overlap the first portion 1011 of the bottom metal layer 1010. Accordingly, the fifth semiconductor layer A5 of each of the first pixel circuit PC1 and the second pixel circuit PC2 may overlap the third portion 1013 of the bottom metal layer 1010.

A first gate insulating layer 103 may be disposed on the silicon semiconductor layer 1110 to cover the silicon semiconductor layer 1110. The first gate insulating layer 103 may be an inorganic insulating layer including an inorganic insulating material such as silicon oxide, silicon nitride, and/or silicon oxynitride. The first gate insulating layer 103 may have a single-layered structure or a multi-layered structure.

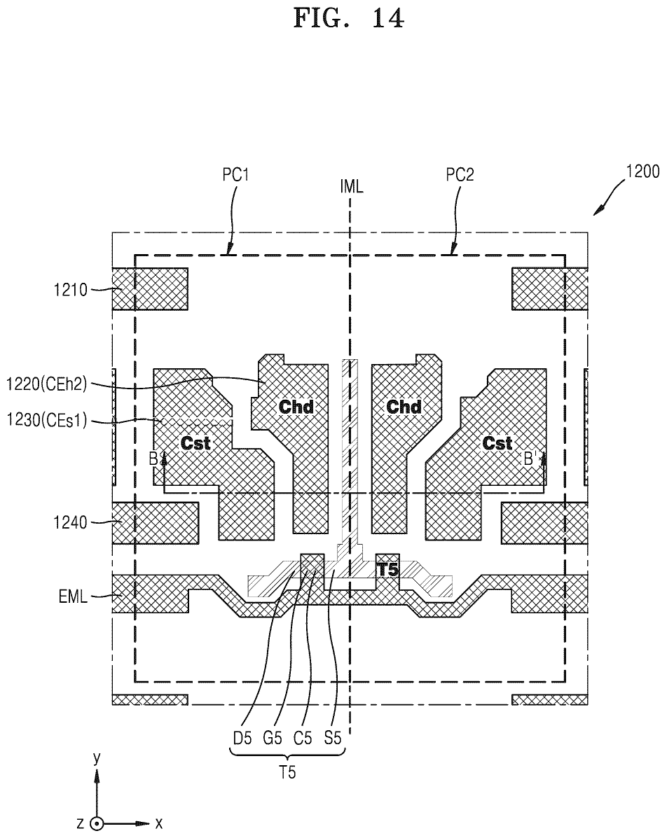

A first gate layer 1200 shown in FIG. 14 may be disposed on the first gate insulating layer 103. For example, FIG. 14 shows, for convenience, the first gate layer 1200 and the silicon semiconductor layer 1110 therebelow in an overlapping manner. It is shown in FIG. 14 that the first gate layer 1200 includes the first emission control line EML, a first conductive layer 1210, a second conductive layer 1220, a third conductive layer 1230, and a fourth conductive layer 1240. The first emission control line EML, the first conductive layer 1210, the second conductive layer 1220, the third conductive layer 1230, and the fourth conductive layer 1240 of the first pixel circuit PC1, and the first emission control line EML, the first conductive layer 1210, the second conductive layer 1220, the third conductive layer 1230, and the fourth conductive layer 1240 of the second pixel circuit PC2 may be approximately symmetrical to each other with respect to the imaginary line IML between the first pixel circuit PC1 and the second pixel circuit PC2.

As shown in FIG. 14, the first conductive layer 1210, the second conductive layer 1220, the third conductive layer 1230, and the fourth conductive layer 1240 may be spaced apart from each other. The first conductive layer 1210, the second conductive layer 1220, the third conductive layer 1230, and the fourth conductive layer 1240 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layered structure or multi-layered structure including these materials. Elements included in the first gate layer 1200 may be simultaneously formed using the same material, and thus, may have the same layer structure.

The first emission control line EML may extend substantially in the first direction (e.g., the x axis direction) to pass across the first pixel circuit PC1 and the second pixel circuit PC2. The first emission control line EML may pass across the pixel circuits arranged in the same row as the first pixel circuit PC1 and the second pixel circuit PC2.

The first emission control line EML may include a fifth gate electrode G5 of the fifth transistor T5 of each of the first pixel circuit PC1 and the second pixel circuit PC2. A portion of the first emission control line EML may protrude to overlap the fifth semiconductor layer A5 of the fifth transistor T5, and the protruded portion of the first emission control line EML may correspond to the fifth gate electrode G5 of the fifth transistor T5. The fifth semiconductor layer A5 of the fifth transistor T5 may include a channel region C5 overlapping the fifth gate electrode G5, and conductive regions S5 and D5 respectively located at two opposite sides of the channel region C5, wherein the conductive regions S5 and D5 are made conductive by being doped with impurities or plasma-processed. One of the conductive regions S5 and D5 may be a source region and the other may be a drain region. The source region and the drain region may respectively correspond to a source electrode and a drain electrode. The positions of the source region and the drain region may be exchanged depending on the properties of the transistor.

The first conductive layer 1210 may have an isolated shape, and the first conductive layers 1210 may be an integral body in two adjacent pixel circuits. As an example, as shown in FIG. 14, the first conductive layer 1210 belonging to the first pixel circuit PC1 may be an integral body with the first conductive layer 1210 of a pixel circuit located in a −x direction, for example, a pixel circuit located in a (j−1)-th column, and the first conductive layer 1210 belonging to the second pixel circuit PC2 may be an integral body with the first conductive layer 1210 of a pixel circuit located in a +x direction, for example, a pixel circuit located in a (j+2)-th column. Each of the second conductive layer 1220 and the third conductive layer 1230 may have an isolated shape. The fourth conductive layer 1240 may also have an isolated shape and be an integral body in the first pixel circuit PC1 and a pixel circuit in a (j−1)-th column, and in addition, be an integral body in the second pixel circuit PC2 and a pixel circuit in a (j+2)-th column. In the first pixel circuit PC1 and the second pixel circuit PC2, the first conductive layer 1210, the second conductive layer 1220, the third conductive layer 1230, and the fourth conductive layer 1240 may be symmetrical to each other with respect to the imaginary line IML described above.

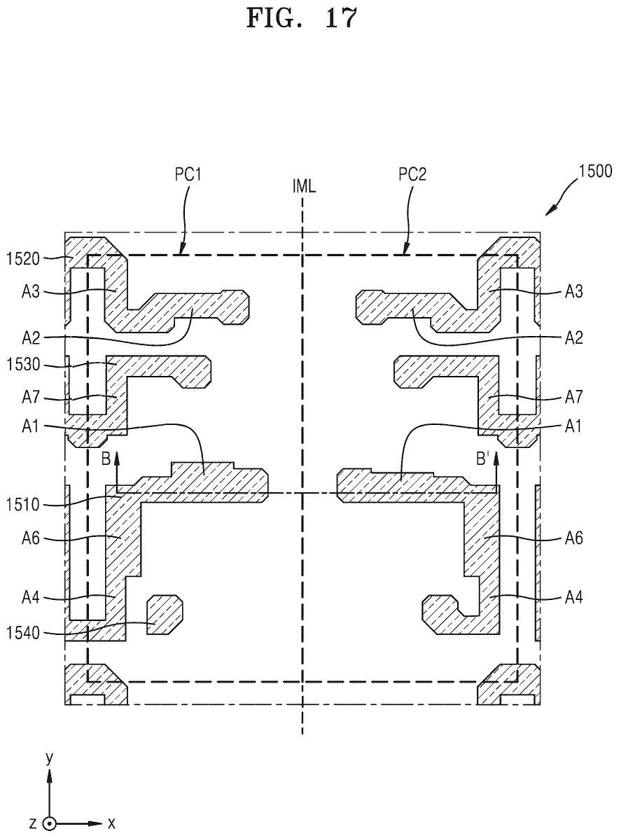

The first conductive layer 1210 may overlap a third semiconductor layer A3 (see FIG. 17) described below. The first conductive layer 1210 may shield at least a portion of light progressing to the third semiconductor layer A3 of the third transistor T3 and protect the third transistor T3 from electrostatic discharge ESD.

The second conductive layer 1220 located in each of the first pixel circuit PC1 and the second pixel circuit PC2 may have an isolated shape, and be located adjacent to the imaginary line IML between the first pixel circuit PC1 and the second pixel circuit PC2. The second conductive layer 1220 may be the second hold electrode CEh2 of the hold capacitor Chd.

The third conductive layer 1230 located in each of the first pixel circuit PC1 and the second pixel circuit PC2 may be the first storage electrode CEs1 of the storage capacitor Cst.

A second gate insulating layer 105 may cover the first gate layer 1200. The second gate insulating layer 105 may be an inorganic insulating layer including an inorganic insulating material such as silicon oxide, silicon nitride, and/or silicon oxynitride. The second gate insulating layer 105 may have a single-layered structure or a multi-layered structure. When needed, the second gate insulating layer 105 may include a material that is different from a material of the first gate insulating layer 103. As an example, the first gate insulating layer 103 may include silicon oxide, and the second gate insulating layer 105 may include silicon nitride.

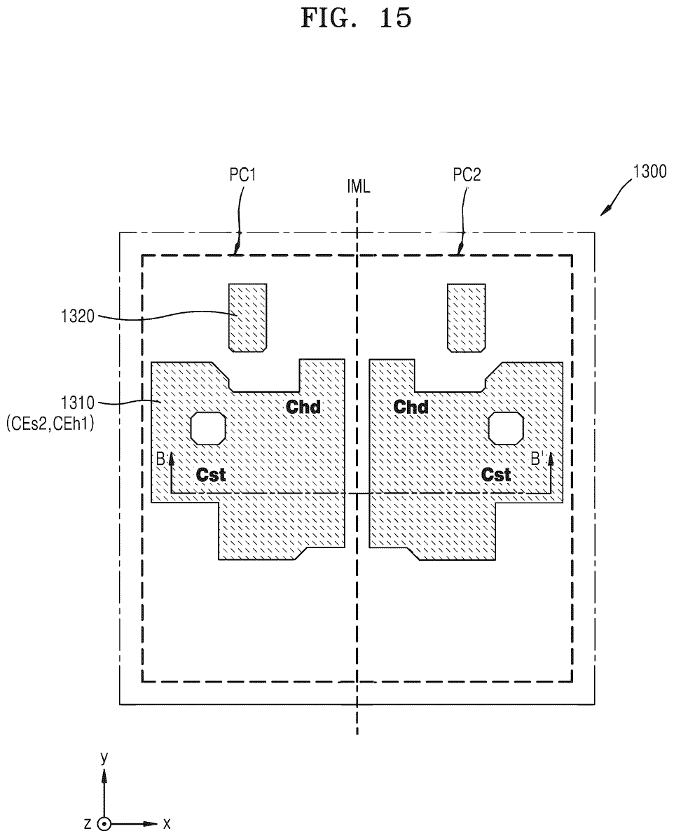

A second gate layer 1300 shown in FIG. 15 may be disposed on the second gate insulating layer 105. It is shown in FIG. 15 that the second gate layer 1300 includes a fifth conductive layer 1310 and a sixth conductive layer 1320. The fifth conductive layer 1310 and the sixth conductive layer 1320 of the first pixel circuit PC1, and the fifth conductive layer 1310 and the sixth conductive layer 1320 of the second pixel circuit PC2 may be approximately symmetrical to each other with respect to the imaginary line IML between the first pixel circuit PC1 and the second pixel circuit PC2.

As shown in FIG. 15, the fifth conductive layer 1310 and the sixth conductive layer 1320 may be spaced apart from each other. The fifth conductive layer 1310 and the sixth conductive layer 1320 may include aluminum (Al), platinum (Pt), palladium (Pd), silver (Ag), magnesium (Mg), gold (Au), Nickel (Ni), neodymium (Nd), iridium (Ir), chromium (Cr), lithium (Li), calcium (Ca), molybdenum (Mo), titanium (Ti), tungsten (W), and/or copper (Cu), and include a single-layered structure or a multi-layered structure including the above materials. Elements included in the second gate layer 1300 may be simultaneously formed using the same material, and thus, may have the same layer structure.

The fifth conductive layer 1310 located in each of the first pixel circuit PC1 and the second pixel circuit PC2 may have an isolated shape. The fifth conductive layer 1310 located in the first pixel circuit PC1 and the fifth conductive layer 1310 located in the second pixel circuit PC2 may be spaced apart from each other and be substantially symmetrical to each other with respect to the imaginary line IML described above. The extension portion ETP of the silicon semiconductor layer 1110 may be located between the fifth conductive layer 1310 located in the first pixel circuit PC1 and the fifth conductive layer 1310 located in the second pixel circuit PC2 in a plan view. The fifth conductive layer 1310 of the first pixel circuit PC1 may overlap the second conductive layer 1220 and the third conductive layer 1230 of the first pixel circuit PC1 located therebelow. The fifth conductive layer 1310 may be the first hold electrode CEh1 of the hold capacitor Chd and the second storage electrode CEs2 of the storage capacitor Cst. For example, the first hold electrode CEh1 of the hold capacitor Chd and the second storage electrode CEs2 of the storage capacitor Cst may be an integral body. Accordingly, the second conductive layer 1220 and the fifth conductive layer 1310 may form the hold capacitor Chd, and the third conductive layer 1230 and the fifth conductive layer 1310 may form the storage capacitor Cst.

The sixth conductive layer 1320 located in each of the first pixel circuit PC1 and the second pixel circuit PC2 may also have an isolated shape. The sixth conductive layer 1320 may overlap a second semiconductor layer A2 (see FIG. 17) described below. The sixth conductive layer 1320 may shield at least a portion of light progressing to the second semiconductor layer A2 of the second transistor T2 and protect the second transistor T2 from electrostatic discharge ESD.

A first interlayer insulating layer 107 may cover the second gate layer 1300. The first interlayer insulating layer 107 may be an inorganic insulating layer including an inorganic insulating material such as silicon oxide, silicon nitride, and/or silicon oxynitride. The first interlayer insulating layer 107 may have a single-layered structure or a multi-layered structure. As an example, the first interlayer insulating layer 107 may have a stack structure of a layer including silicon oxide and a layer including silicon nitride.

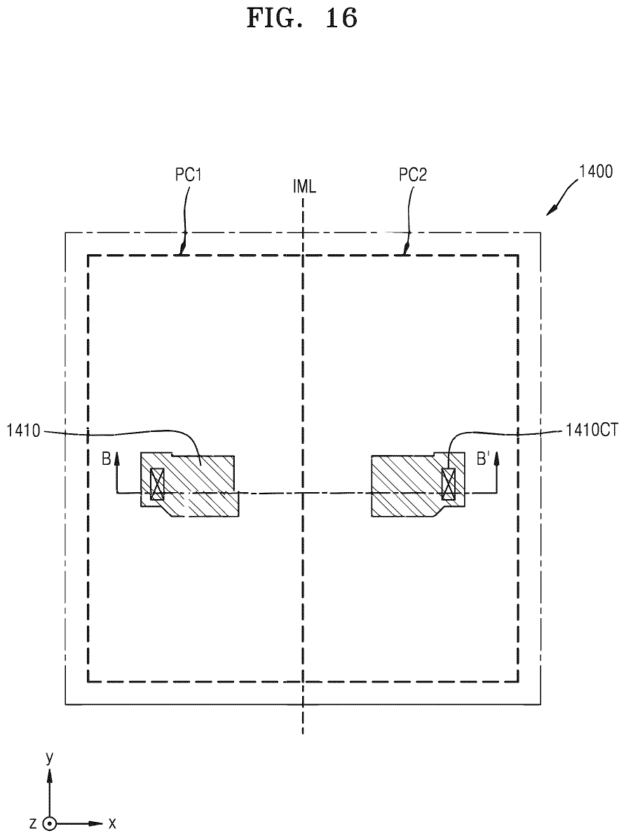

An intermediate conductive layer 1400 shown in FIG. 16 may be disposed on the first interlayer insulating layer 107. It is shown in FIG. 16 that the intermediate conductive layer 1400 includes a shield layer 1410. The shield layer 1410 of the first pixel circuit PC1 and the shield layer 1410 of the second pixel circuit PC2 may be approximately symmetrical to each other with respect to the imaginary line IML between the first pixel circuit PC1 and the second pixel circuit PC2.

The shield layer 1410 may include aluminum (Al), platinum (Pt), palladium (Pd), silver (Ag), magnesium (Mg), gold (Au), Nickel (Ni), neodymium (Nd), iridium (Ir), chromium (Cr), lithium (Li), calcium (Ca), molybdenum (Mo), titanium (Ti), tungsten (W), and/or copper (Cu), and include a single-layered structure or a multi-layered structure including the above materials. As an example, the shield layer 1410 may have a single-layered structure including molybdenum or titanium.

The shield layer 1410 located in each of the first pixel circuit PC1 and the second pixel circuit PC2 may have an isolated shape. The shield layer 1410 may overlap a first semiconductor layer A1 (see FIG. 17) described below. The shield layer 1410 may shield at least a portion of light progressing to the first semiconductor layer A1 of the first transistor T1 and protect the first transistor T1 from electrostatic discharge ESD. The shield layer 1410 may be connected to the fifth conductive layer 1310 through a contact hole 1410CT formed in the first interlayer insulating layer 107 thereunder. Accordingly, the shield layer 1410 may have the same electrical potential as the first hold electrode CEh1 of the hold capacitor Chd and the fifth conductive layer 1310, which is the second storage electrode CEs2 of the storage capacitor Cst.

A second interlayer insulating layer 108 may be disposed over the intermediate conductive layer 1400. The second interlayer insulating layer 108 may be an inorganic insulating layer including an inorganic insulating material such as silicon oxide, silicon nitride, and/or silicon oxynitride. The second interlayer insulating layer 108 may have a single-layered structure or a multi-layered structure. As an example, the second interlayer insulating layer 108 may have a stack structure of a layer including silicon oxide and a layer including silicon nitride.

A semiconductor layer 1500 shown in FIG. 17 may be disposed on the second interlayer insulating layer 108. The semiconductor layer 1500 may include an oxide semiconductor. The oxide semiconductor may include at least one selected from a group including indium (In), gallium (Ga), tin (Sn), zirconium (Zr), vanadium (V), hafnium (Hf), cadmium (Cd), germanium (Gc), chromium (Cr), titanium (Ti), aluminum (Al), cesium (Cs), cerium (Ce), and zinc (Zn). As an example, the oxide semiconductor may include ITZO (InSnZnO) or IGZO (InGaZnO). It is shown in FIG. 17 that the semiconductor layer 1500 includes a first oxide semiconductor pattern 1510, a second oxide semiconductor pattern 1520, a third oxide semiconductor pattern 1530, and a fourth oxide semiconductor pattern 1540. As shown in FIG. 17, the first oxide semiconductor pattern 1510, the second oxide semiconductor pattern 1520, the third oxide semiconductor pattern 1530, and the fourth oxide semiconductor pattern 1540 may be spaced apart from each other.

The first oxide semiconductor pattern 1510 located in each of the first pixel circuit PC1 and the second pixel circuit PC2 may have an isolated shape. The first oxide semiconductor pattern 1510 may include the first semiconductor layer A1, a fourth semiconductor layer A4, and a sixth semiconductor layer A6. For example, the first semiconductor layer A1, the fourth semiconductor layer A4, and the sixth semiconductor layer A6 of the first pixel circuit PC1 may be an integral body, and the first semiconductor layer A1, the fourth semiconductor layer A4, and the sixth semiconductor layer A6 of the second pixel circuit PC2 may be an integral body. The first oxide semiconductor pattern 1510 may have a shape bent by serval times.

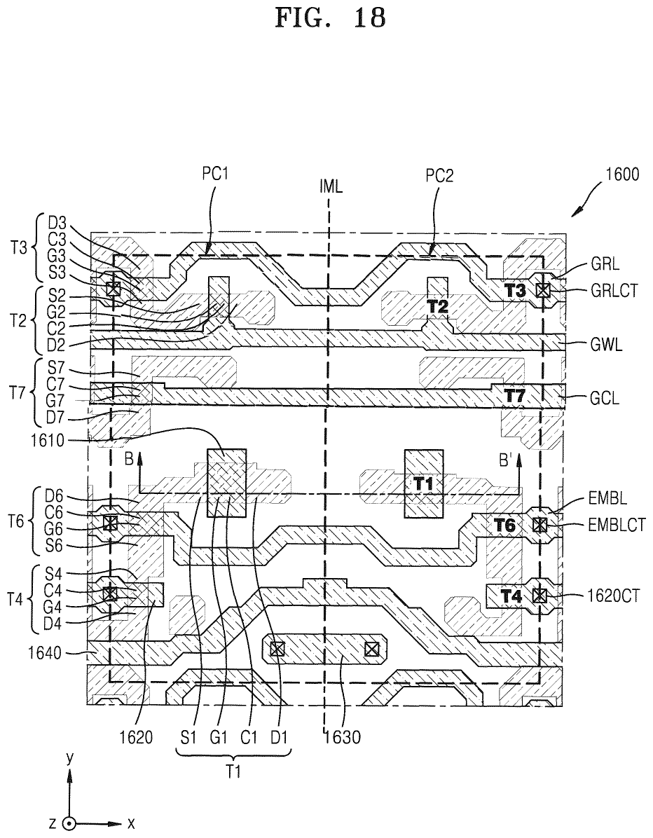

The first semiconductor layer A1, the fourth semiconductor layer A4, and the sixth semiconductor layer A6 included in the first oxide semiconductor pattern 1510 may respectively overlap a first gate electrode 1610, the seventh conductive layer 1620, and the second emission control line EMBL described below with reference to FIG. 18. For example, a portion of the first oxide semiconductor pattern 1510 overlapping the first gate electrode 1610 may be the first semiconductor layer A1, a portion of the first oxide semiconductor pattern 1510 overlapping the seventh conductive layer 1620 may be the fourth semiconductor layer A4, and a portion of the first oxide semiconductor pattern 1510 overlapping the second emission control line EMBL may be the sixth semiconductor layer A6.

For example, in a plan view, the shape of the first oxide semiconductor pattern 1510 of the first pixel circuit PC1 and the shape of the first oxide semiconductor pattern 1510 of the second pixel circuit PC2 may be different from each other. The first oxide semiconductor pattern 1510 of the first pixel circuit PC1 may be an integral body with a first oxide semiconductor pattern of a pixel circuit located in the same row as the first pixel circuit PC1 and in an adjacent column, for example, a pixel circuit extending in a direction to a pixel circuit located in an i-th row and a (j−1)-th column, the pixel circuit being located in a (j−1)-th column. Unlike this, the first oxide semiconductor pattern 1510 of the second pixel circuit PC2 may have an isolated shape. When needed, the first oxide semiconductor pattern 1510 of the first pixel circuit PC1 may also have an isolated shape. In this case, the first oxide semiconductor pattern 1510 of the first pixel circuit PC1 and the first oxide semiconductor pattern 1510 of the second pixel circuit PC2 may be approximately symmetrical to each other with respect to the imaginary line IML between the first pixel circuit PC1 and the second pixel circuit PC2.

The second oxide semiconductor pattern 1520 disposed in each of the first pixel circuit PC1 and the second pixel circuit PC2 may have an isolated shape and be an integral body in two adjacent pixel circuits. As an example, as shown in FIG. 17, the second oxide semiconductor pattern 1520 belonging to the first pixel circuit PC1 may be an integral body with the second oxide semiconductor pattern 1520 of a pixel circuit located in the −x direction, for example, a pixel circuit located in a (j−1)-th column, and the second oxide semiconductor pattern 1520 belonging to the second pixel circuit PC2 may be an integral body with the second oxide semiconductor pattern 1520 of a pixel circuit located in the +x direction, for example, a pixel circuit located in a (j+2)-th column. The second oxide semiconductor pattern 1520 of the first pixel circuit PC1 and the second oxide semiconductor pattern 1520 of the second pixel circuit PC2 may be approximately symmetrical to each other with respect to the imaginary line IML described above.

The second oxide semiconductor pattern 1520 may include the second semiconductor layer A2 of the second transistor T2 and the third semiconductor layer A3 of the third transistor T3. For example, the second semiconductor layer A2 of the second transistor T2 and the third semiconductor layer A3 of the third transistor T3 may be integrally connected to each other. The second semiconductor layer A2 and the third semiconductor layer A3 of the second oxide semiconductor pattern 1520 may overlap the scan line GWL and the first reference gate line GRL described below with reference to FIG. 18. For example, a portion of the second oxide semiconductor pattern 1520 overlapping the scan line GWL may be the second semiconductor layer A2, and a portion of the second oxide semiconductor pattern 1520 overlapping the first reference gate line GRL may be the third semiconductor layer A3.

The third oxide semiconductor pattern 1530 disposed in each of the first pixel circuit PC1 and the second pixel circuit PC2 may have an isolated shape and be an integral body in two adjacent pixel circuits. As an example, as shown in FIG. 17, the third oxide semiconductor pattern 1530 belonging to the first pixel circuit PC1 may be an integral body with the third oxide semiconductor pattern 1530 of a pixel circuit disposed in the −x direction, for example, a pixel circuit disposed in a (j−1)-th column, and the third oxide semiconductor pattern 1530 belonging to the second pixel circuit PC2 may be an integral body with the third oxide semiconductor pattern 1530 of a pixel circuit disposed in the +x direction, for example, a pixel circuit disposed in a (j+2)-th column. The third oxide semiconductor pattern 1530 of the first pixel circuit PC1 and the third oxide semiconductor pattern 1530 of the second pixel circuit PC2 may be approximately symmetrical to each other with respect to the imaginary line IML described above.

The third oxide semiconductor pattern 1530 may include a seventh semiconductor layer A7 of the seventh transistor T7. The seventh semiconductor layer A7 of the third oxide semiconductor pattern 1530 may overlap the second reference gate line GCL described below with reference to FIG. 18. For example, a portion of the third oxide semiconductor pattern 1530 overlapping the second reference gate line GCL may be the seventh semiconductor layer A7.

The fourth oxide semiconductor pattern 1540 may be disposed in the first pixel circuit PC1. The fourth oxide semiconductor pattern 1540 may be disposed at a position corresponding to one end of the first oxide semiconductor pattern 1510 of the second pixel circuit PC2 and may correspond to a type of dummy electrode.

Each of the first oxide semiconductor pattern 1510, the second oxide semiconductor pattern 1520, the third oxide semiconductor pattern 1530, and the fourth oxide semiconductor pattern 1540 may include at least a partially conductive region. As an example, at least a portion of each of the first oxide semiconductor pattern 1510, the second oxide semiconductor pattern 1520, the third oxide semiconductor pattern 1530, and the fourth oxide semiconductor pattern 1540 may be doped or plasma processed, and accordingly, the processed portion may be made conductive.

A third gate insulating layer 109 may cover the semiconductor layer 1500. The third gate insulating layer 109 may be an inorganic insulating layer including an inorganic insulating material such as silicon oxide, silicon nitride, and/or silicon oxynitride. The third gate insulating layer 109 may have a single-layered structure or a multi-layered structure.

A third gate layer 1600 shown in FIG. 18 may be disposed on the third gate insulating layer 109. FIG. 18 shows, for convenience, the third gate layer 1600 and the semiconductor layer 1500 therebelow in an overlapping manner. It is shown in FIG. 18 that the third gate layer 1600 includes the first gate electrode 1610, the seventh conductive layer 1620, a eighth conductive layer 1630, the first reference gate line GRL, the scan line GWL, the second reference gate line GCL, the second emission control line EMBL, and an auxiliary power line 1640. The elements in the first pixel circuit PC1 and the elements in the second pixel circuit PC2 may be approximately symmetrical to each other with respect to the imaginary line IML between the first pixel circuit PC1 and the second pixel circuit PC2.

The first gate electrode 1610, the seventh conductive layer 1620, the eighth conductive layer 1630, the first reference gate line GRL, the scan line GWL, the second reference gate line GCL, the second emission control line EMBL, and the auxiliary power line 1640 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layered structure or a multi-layered structure including these materials. Elements included in the third gate layer 1600 may be simultaneously formed using the same material, and thus, may have the same layer structure.

The first gate electrode 1610 of each of the first pixel circuit PC1 and the second pixel circuit PC2 may have an isolated shape and be a gate electrode of the first transistor T1. A portion of the first oxide semiconductor pattern 1510 overlapping the first gate electrode 1610 may be a channel region C1, and two opposite sides of the channel region C1 may be conductive regions S1 and D1 made conductive by being doped with impurities or plasma-processed. One of the conductive regions S1 and D1 may be a source region and the other may be a drain region. The source region and the drain region may correspond to a source electrode and a drain electrode. The positions of the source region and the drain region may be exchanged depending on the properties of the transistor.

The seventh conductive layer 1620 disposed in each of the first pixel circuit PC1 and the second pixel circuit PC2 may have an isolated shape and be an integral body in two adjacent pixel circuits. As an example, as shown in FIG. 18, the seventh conductive layer 1620 belonging to the first pixel circuit PC1 may be an integral body with the seventh conductive layer 1620 of a pixel circuit disposed in the −x direction, for example, a pixel circuit disposed in a (j−1)-th column, and the seventh conductive layer 1620 belonging to the second pixel circuit PC2 may be an integral body with the seventh conductive layer 1620 of a pixel circuit disposed in the +x direction, for example, a pixel circuit disposed in a (j+2)-th column.

The seventh conductive layer 1620 may be a gate electrode of the fourth transistor T4. A portion of the seventh conductive layer 1620 may correspond to a fourth gate electrode G4, a portion of the first oxide semiconductor pattern 1510 overlapping the seventh conductive layer 1620 may be a channel region C4, and two opposite sides of the channel region C4 may be conductive regions S4 and D4 made conductive by being doped with impurities or plasma-processed. One of the conductive regions S4 and D4 may be a source region and the other may be a drain region. The source region and the drain region may correspond to a source electrode and a drain electrode. The positions of the source region and the drain region may be exchanged depending on the properties of the transistor. The seventh conductive layer 1620 may be connected to the first emission control line EML through a contact hole 1620CT formed in the second gate insulating layer 105, the first interlayer insulating layer 107, the second interlayer insulating layer 108, and the third gate insulating layer 109.

The eighth conductive layer 1630 may be disposed over the first pixel circuit PC1 and the second pixel circuit PC2 and have an isolated shape. The eighth conductive layer 1630 may be connected to the horizontal connection line DHL described below and may electrically connect disconnected portions of the horizontal connection line DHL. This is described below.

The first reference gate line GRL may extend substantially in the first direction (e.g., the x axis direction) to pass across the first pixel circuit PC1 and the second pixel circuit PC2. The first reference gate line GRL may pass across the pixel circuits arranged in the same row as the first pixel circuit PC1 and the second pixel circuit PC2. The first reference gate line GRL may be connected to the first conductive layer 1210 through a contact hole GRLCT formed in the second gate insulating layer 105, the first interlayer insulating layer 107, the second interlayer insulating layer 108, and the third gate insulating layer 109. A portion of the first reference gate line GRL may correspond to a third gate electrode G3, a portion of the second oxide semiconductor pattern 1520 corresponding to the first reference gate line GRL may be a channel region C3, and two opposite sides of the channel region C3 may be conductive regions S3 and D3 made conductive by being doped with impurities or plasma-processed. One of the conductive regions S3 and D3 may be a source region and the other may be a drain region. The source region and the drain region may correspond to a source electrode and a drain electrode. The positions of the source region and the drain region may be exchanged depending on the properties of the transistor.

The scan line GWL may extend substantially in the first direction (e.g., the x axis direction) to pass across the first pixel circuit PC1 and the second pixel circuit PC2. The scan line GWL may pass across the pixel circuits arranged in the same row as the first pixel circuit PC1 and the second pixel circuit PC2. A portion of the scan line GWL may correspond to a second gate electrode G2, a portion of the second oxide semiconductor pattern 1520 corresponding to the scan line GWL may be a channel region C2, and two opposite sides of the channel region C2 may be conductive regions S2 and D2 made conductive by being doped with impurities or plasma-processed. One of the conductive regions S2 and D2 may be a source region and the other may be a drain region. The source region and the drain region may correspond to a source electrode and a drain electrode. The positions of the source region and the drain region may be exchanged depending on the properties of the transistor.

The second reference gate line GCL may extend substantially in the first direction (e.g., the x axis direction) to pass across the first pixel circuit PC1 and the second pixel circuit PC2. The second reference gate line GCL may pass across the pixel circuits arranged in the same row as the first pixel circuit PC1 and the second pixel circuit PC2. A portion of the second reference gate line GCL may correspond to a seventh gate electrode G7, a portion of the third oxide semiconductor pattern 1530 corresponding to the second reference gate line GCL may be a channel region C7, and two opposite sides of the channel region C7 may be conductive regions S7 and D7 made conductive by being doped with impurities or plasma-processed. One of the conductive regions S7 and D7 may be a source region and the other may be a drain region. The source region and the drain region may correspond to a source electrode and a drain electrode. The positions of the source region and the drain region may be exchanged depending on the properties of the transistor.

The second emission control line EMBL may extend substantially in the first direction (e.g., the x axis direction) to pass across the first pixel circuit PC1 and the second pixel circuit PC2. The second emission control line EMBL may pass across the pixel circuits arranged in the same row as the first pixel circuit PC1 and the second pixel circuit PC2. The second emission control line EMBL may be connected to the fourth conductive layer 1240 through a contact hole EMBLCT formed in the second gate insulating layer 105, the first interlayer insulating layer 107, the second interlayer insulating layer 108, and the third gate insulating layer 109. A portion of the second emission control line EMBL may correspond to a sixth gate electrode G6, a portion of the first oxide semiconductor pattern 1510 corresponding to the second emission control line EMBL may be a channel region C6, and two opposite sides of the channel region C6 may be conductive regions S6 and D6 made conductive by being doped with impurities or plasma-processed. One of the conductive regions S6 and D6 may be a source region and the other may be a drain region. The source region and the drain region may correspond to a source electrode and a drain electrode. The positions of the source region and the drain region may be exchanged depending on the properties of the transistor.

The auxiliary power line 1640 may extend substantially in the first direction (e.g., the x axis direction) to pass across the first pixel circuit PC1 and the second pixel circuit PC2. The auxiliary power line 1640 may pass across the pixel circuits arranged in the same row as the first pixel circuit PC1 and the second pixel circuit PC2. The auxiliary power line 1640 is connected to the driving voltage line PL described below, and accordingly, a set of auxiliary power lines 1640 and driving voltage lines PL may be made to have a mesh structure in the display area DA.

A third interlayer insulating layer 111 may cover the third gate layer 1600. The third interlayer insulating layer 111 may be an inorganic insulating layer including an inorganic insulating material such as silicon oxide, silicon nitride, and/or silicon oxynitride. The third interlayer insulating layer 111 may have a single-layered structure or a multi-layered structure. As an example, the third interlayer insulating layer 111 may have a stack structure of a layer including silicon oxide and a layer including silicon nitride. The third interlayer insulating layer 111 may be an organic insulating layer including an organic insulating material such as acryl, benzocyclobutene (BCB), polyimide, or hexamethyldisiloxane (HMDSO).

A first source drain layer 1700 shown in FIG. 19 may be disposed on the third interlayer insulating layer 111. It is shown in FIG. 19 that the first source drain layer 1700 includes the driving voltage line PL, a first connection electrode 1720, a second connection electrode 1730, a third connection electrode 1740, a fourth connection electrode 1750, a fifth connection electrode 1760, a sixth connection electrode 1772, a seventh connection electrode 1774, an eighth connection electrode 1776, a dummy connection electrode 1776′, and the horizontal connection line DHL. The elements in the first pixel circuit PC1 and the elements in the second pixel circuit PC2 may be approximately symmetrical to each other with respect to the imaginary line IML between the first pixel circuit PC1 and the second pixel circuit PC2.

The driving voltage line PL, the first connection electrode 1720, the second connection electrode 1730, the third connection electrode 1740, the fourth connection electrode 1750, the fifth connection electrode 1760, the sixth connection electrode 1772, the seventh connection electrode 1774, the eighth connection electrode 1776, and the horizontal connection line DHL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layered structure or multi-layered structure including these materials. Elements included in the first source drain layer 1700 may be simultaneously formed using the same material, and thus, may have the same layer structure.

The driving voltage line PL may have a shape extending in the second direction (e.g., the y axis direction) along the imaginary line IML between the first pixel circuit PC1 and the second pixel circuit PC2. The driving voltage line PL may be connected to the auxiliary power line 1640 through a contact hole PLCT1 formed in the third interlayer insulating layer 111 thereunder. Through this connection structure, the plurality of driving voltage lines PL and the plurality of auxiliary power lines 1640 may form a mesh structure in the display area DA, and through this, a voltage drop (IR drop) of the driving voltage ELVDD may be minimized. In addition, the driving voltage line PL may be connected to the silicon semiconductor layer 1110 through a contact hole PLCT2 formed in the first gate insulating layer 103, the second gate insulating layer 105, the first interlayer insulating layer 107, the second interlayer insulating layer 108, the third gate insulating layer 109, and the third interlayer insulating layer 111. Through this, the silicon semiconductor layer 1110 may be made to have an electrical potential that is equal or similar to the driving voltage ELVDD.

The first connection electrode 1720 disposed in each of the first pixel circuit PC1 and the second pixel circuit PC2 may have an isolated shape. The first connection electrode 1720 may be electrically connected to the first semiconductor layer A1 of the first transistor T1 through a contact hole 1720CT1 formed in the third gate insulating layer 109 and the third interlayer insulating layer 111. In addition, the first connection electrode 1720 may be connected to the fifth semiconductor layer A5 of the fifth transistor T5 through a contact hole 1720CT2 formed in the first gate insulating layer 103, the second gate insulating layer 105, the first interlayer insulating layer 107, the second interlayer insulating layer 108, the third gate insulating layer 109, and the third interlayer insulating layer 111. Accordingly, the first connection electrode 1720 may electrically connect the first transistor T1 and the fifth transistor T5 to each other.

The second connection electrode 1730 disposed in each of the first pixel circuit PC1 and the second pixel circuit PC2 may have an isolated shape. The second connection electrode 1730 may correspond to the first node N1 in the pixel circuit PC of FIG. 10. The second connection electrode 1730 may be electrically connected to the first gate electrode 1610 of the first transistor T1 through a contact hole 1730CT3 formed in the third interlayer insulating layer 111. In addition, the second connection electrode 1730 may be electrically connected to the third semiconductor layer A3 through a contact hole 1730CT1 formed in the third gate insulating layer 109 and the third interlayer insulating layer 111. In addition, the second connection electrode 1730 passes through an opening formed in the fifth conductive layer 1310 through a contact hole 1730CT2 formed in the second gate insulating layer 105, the first interlayer insulating layer 107, the second interlayer insulating layer 108, the third gate insulating layer 109, and the third interlayer insulating layer 111, and be electrically connected to the third conductive layer 1230. Accordingly, the second connection electrode 1730 may electrically connect the first gate electrode G1 of the first transistor T1, the third transistor T3, and the first storage electrode CEs1 to each other.

The third connection electrode 1740 disposed in each of the first pixel circuit PC1 and the second pixel circuit PC2 may have an isolated shape. The third connection electrode 1740 may correspond to the second node N2 in the pixel circuit PC of FIG. 10. The third connection electrode 1740 may be electrically connected to the fifth conductive layer 1310 including the second storage electrode CEs2 and the second hold electrode CEh2 through a contact hole 1740CT1 formed in the first interlayer insulating layer 107, the second interlayer insulating layer 108, the third gate insulating layer 109, and the third interlayer insulating layer 111. In addition, the third connection electrode 1740 may be electrically connected to the first oxide semiconductor pattern 1510 through a contact hole 1740CT2 formed in the third gate insulating layer 109 and the third interlayer insulating layer 111. A connection point of the third connection electrode 1740 and the first oxide semiconductor pattern 1510 may be disposed between a region of the first oxide semiconductor pattern 1510 corresponding to the first semiconductor layer A1 and a region of the first oxide semiconductor pattern 1510 corresponding to the sixth semiconductor layer A6 (see, FIG. 17). Through this, the third connection electrode 1740 may electrically connect the second storage electrode CEs2, the second hold electrode CEh2, the first transistor T1, and the sixth transistor T6 to each other.

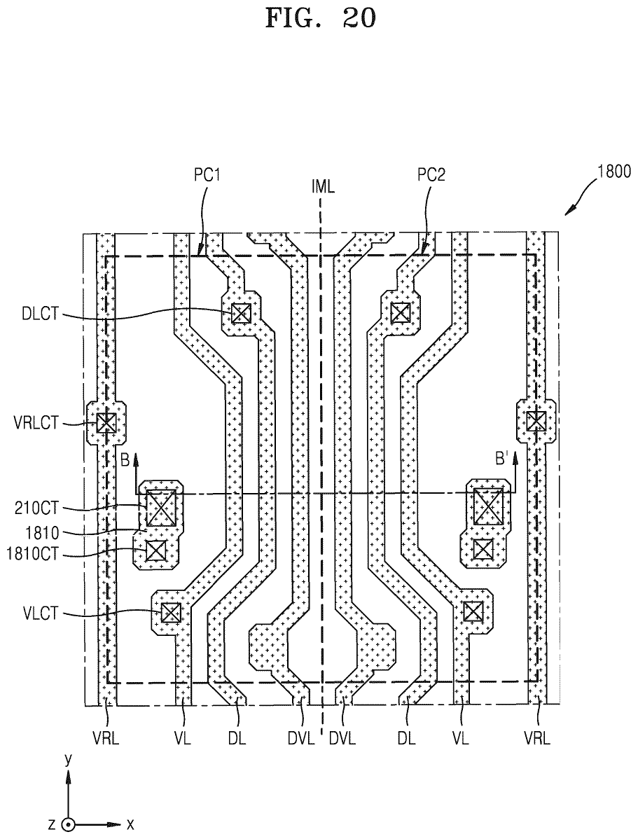

The fourth connection electrode 1750 disposed in each of the first pixel circuit PC1 and the second pixel circuit PC2 has an isolated shape, and may be an integral body in the first pixel circuit PC1 and a pixel circuit disposed in a (j−1)-th column, and also, be an integral body in the second pixel circuit PC2 and a pixel circuit disposed in a (j+2)-th column. The fourth connection electrode 1750 may be electrically connected to the third semiconductor layer A3 through a contact hole 1750CT1 formed in the third gate insulating layer 109 and the third interlayer insulating layer 111. In addition, the fourth connection electrode 1750 may be electrically connected to the seventh semiconductor layer A7 through a contact hole 1750CT2 formed in the third gate insulating layer 109 and the third interlayer insulating layer 111. The fourth connection electrode 1750 may be electrically connected to the reference voltage line VRL (see, FIG. 20) described below and may transfer the reference voltage VREF to the third transistor T3 and the seventh transistor T7.

The fifth connection electrode 1760 disposed in each of the first pixel circuit PC1 and the second pixel circuit PC2 may have an isolated shape. In addition, the fifth connection electrode 1760 may be electrically connected to the second conductive layer 1220, which is the first hold electrode CEh1 of the hold capacitor Chd through a contact hole 1760CT1 formed in the second gate insulating layer 105, the first interlayer insulating layer 107, the second interlayer insulating layer 108, the third gate insulating layer 109, and the third interlayer insulating layer 111. In addition, the fifth connection electrode 1760 may be electrically connected to the seventh semiconductor layer A7 through a contact hole 1760CT2 formed in the third gate insulating layer 109 and the third interlayer insulating layer 111. Through this, the fifth connection electrode 1760 may electrically connect the first hold electrode CEh1 and the seventh transistor T7 to each other.

The sixth connection electrode 1772 disposed in each of the first pixel circuit PC1 and the second pixel circuit PC2 may have an isolated shape. The sixth connection electrode 1772 may be electrically connected to the second semiconductor layer A2 through a contact hole 1772CT formed in the third gate insulating layer 109 and the third interlayer insulating layer 111. The sixth connection electrode 1772 may be electrically connected to the data line DL (see, FIG. 20) to transfer a data signal DATA to the second transistor T2.

The seventh connection electrode 1774 disposed in each of the first pixel circuit PC1 and the second pixel circuit PC2 may have an isolated shape. The seventh connection electrode 1774 may be electrically connected to the fourth semiconductor layer A4 of the fourth transistor T4 through a contact hole 1774CT formed in the third gate insulating layer 109 and the third interlayer insulating layer 111. The seventh connection electrode 1774 may be electrically connected to a pixel electrode 210 of the light-emitting diode LED as described below.

The eighth connection electrode 1776 disposed in the second pixel circuit PC2 may have an isolated shape. In the second pixel circuit PC2, the eighth connection electrode 1776 may be electrically connected to the fourth semiconductor layer A4 of the fourth transistor T4 through a contact hole 1776CT formed in the third gate insulating layer 109 and the third interlayer insulating layer 111. As described below, the eighth connection electrode 1776 may be electrically connected to the initialization voltage line VL (see, FIG. 20) passing across the second pixel circuit PC2 to transfer the initialization voltage VINT to the fourth transistor T4. For example, the fourth transistor T4 disposed in the first pixel circuit PC1 disposed in a j-th column is electrically connected to a fourth transistor of a pixel circuit disposed in a (j−1)-th column (adjacent in the −x direction) as shown in FIG. 17. Accordingly, the fourth transistor T4 disposed in the first pixel circuit PC1 may be electrically connected to an initialization voltage line passing across a pixel circuit disposed in a (j−1)-th column (adjacent in the −x direction) instead of the initialization voltage line VL (see, FIG. 20) passing across the first pixel circuit PC1.

The dummy connection electrode 1776′ disposed in the first pixel circuit PC1 may have an isolated shape. The dummy connection electrode 1776′ may be electrically connected to the fourth oxide semiconductor pattern 1540, which is also a dummy pattern, through a contact hole 1776CT′. For example, the dummy connection electrode 1776′ and the eighth connection electrode 1776 may be symmetrical to each other with respect to the imaginary line IML.

The horizontal connection lines DHL extending substantially in the first direction (e.g., the x axis direction) but disconnected by the driving voltage line PL, may be electrically connected to the eighth conductive layer 1630 through contact holes DHLCT formed in the third interlayer insulating layer 111. Accordingly, a set of the eighth conductive layer 1630 and the horizontal connection line DHL described below may correspond to a portion of the data transfer line DTL described with reference to FIG. 8 or 9, for example, one of the first horizontal connection line DHL1, the second horizontal connection line DHL2, and the third horizontal connection line DHL3. In the case where the horizontal connection line DHL needs to be electrically connected to the vertical connection line DVL (see, FIG. 20) described below, the horizontal connection line DHL may be electrically connected to the vertical connection line DVL at a portion where the contact hole DHLCT is disposed.

A fourth interlayer insulating layer 113 may be disposed on the first source drain layer 1700 described with reference to FIG. 19. The fourth interlayer insulating layer 113 may be an inorganic insulating layer including an inorganic insulating material such as silicon oxide, silicon nitride, and/or silicon oxynitride. The fourth interlayer insulating layer 113 may have a single-layered structure or a multi-layered structure. As an example, the fourth interlayer insulating layer 113 may have a stack structure of a layer including silicon oxide and a layer including silicon nitride. The fourth interlayer insulating layer 113 may be an organic insulating layer including an organic insulating material such as acryl, benzocyclobutene (BCB), polyimide, or hexamethyldisiloxane (HMDSO).

A second source drain layer 1800 shown in FIG. 20 may be disposed on the fourth interlayer insulating layer 113. It is shown in FIG. 20 that the second source drain layer 1800 includes the data line DL, the vertical connection line DVL, the initialization voltage line VL, the reference voltage line VRL, and a ninth connection electrode 1810. The elements in the first pixel circuit PC1 and the elements in the second pixel circuit PC2 may be approximately symmetrical to each other with respect to the imaginary line IML between the first pixel circuit PC1 and the second pixel circuit PC2.

Each of the data line DL, the vertical connection line DVL, the initialization voltage line VL, and the reference voltage line VRL may extend in the second direction (e.g., the y axis direction). The data line DL, the vertical connection line DVL, the initialization voltage line VL, and the reference voltage line VRL passing across the first pixel circuit PC1, and the data line DL, the vertical connection line DVL, the initialization voltage line VL, and the reference voltage line VRL passing across the second pixel circuit PC2 may be substantially symmetrical to each other with respect to the imaginary line IML.

The data line DL passing across each of the first pixel circuit PC1 and the second pixel circuit PC2 may be electrically connected to the sixth connection electrode 1772 described with reference to FIG. 19 through a contact hole DLCT formed in the fourth interlayer insulating layer 113 to provide data signals to the second transistor T2.

The vertical connection line DVL passing across each of the first pixel circuit PC1 and the second pixel circuit PC2 may correspond to a portion of the data transfer line DTL described with reference to FIG. 8 or 9, for example, one of the first vertical connection line DVL1, the second vertical connection line DVL2, the third vertical connection line DVL3, the first additional vertical connection line DVL1′, the second additional vertical connection line DVL2′, and the third additional vertical connection line DVL3′. Because the vertical connection line DVL includes a portion protruding in the first direction (e.g., the x axis direction), in the case where the vertical connection line DVL needs to be electrically connected to the horizontal connection line DHL disposed therebelow, the vertical connection line DVL may be electrically connected to the horizontal connection line DHL through a contact hole formed in the fourth interlayer insulating layer 113 in the protruded portion.

The initialization voltage line VL passing across the second pixel circuit PC2 may be electrically connected to the eighth connection electrode 1776 therebelow through a contact hole VLCT formed in the fourth interlayer insulating layer 113, and the eighth connection electrode 1776 may be electrically connected to the first oxide semiconductor pattern 1510 therebelow through a contact hole 1776CT to transfer the initialization voltage to the fourth transistor T4 of the second pixel circuit PC2.

The initialization voltage line VL passing across the first pixel circuit PC1 may be electrically connected to the dummy connection electrode 1776′ through the contact hole VLCT formed in the fourth interlayer insulating layer 113. As described above with reference to FIG. 19, the fourth transistor T4 disposed in the first pixel circuit PC1 disposed in a j-th column is electrically connected to a fourth transistor of a pixel circuit disposed in a (j−1)-th column (adjacent in the −x direction) as shown in FIG. 17. Accordingly, the fourth transistor T4 disposed in the first pixel circuit PC1 may be electrically connected to an initialization voltage line passing across a pixel circuit disposed in a (j−1)-th column (adjacent in the −x direction) instead of the first initialization voltage line VL passing across the first pixel circuit PC1.

The semiconductor layer 1500 may be symmetrical with respect to the imaginary line IML in the first pixel circuit PC1 and the second pixel circuit PC2, and accordingly, the fourth oxide semiconductor pattern 1540 of the first pixel circuit PC1 may be an integral body with the first oxide semiconductor pattern 1510. In this case, the initialization voltage line VL passing across the first pixel circuit PC1 may be electrically connected to the fourth transistor T4 of the first pixel circuit PC1.

The reference voltage line VRL passing across each of the first pixel circuit PC1 and the second pixel circuit PC2 may be electrically connected to the fourth connection electrode 1750 described with reference to FIG. 19 through a contact hole VRLCT formed in the fourth interlayer insulating layer 113. As described above, the fourth connection electrode 1750 may be electrically connected to the second oxide semiconductor pattern 1520 and the third oxide semiconductor pattern 1530 to provide the reference voltage to the third transistor T3 and the seventh transistor T7.

For example, the first pixel circuit PC1 disposed in a j-th column may share the reference voltage line VRL with a pixel circuit disposed in a (j−1)-th column adjacent in the −x direction, and the second pixel circuit PC2 disposed in a (j+1)-th column may share the reference voltage line VRL with a pixel circuit disposed in a (j+2)-th column adjacent in the +x direction.

Each ninth connection electrode 1810 may have an isolated shape. The ninth connection electrode 1810 disposed in each of the first pixel circuit PC1 and the second pixel circuit PC2 may be electrically connected to the seventh connection electrode 1774 described with reference to FIG. 19 through a contact hole 1810CT formed in the fourth interlayer insulating layer 113. The ninth connection electrode 1810 may also be electrically connected to the pixel electrode 210 in the upper portion through a contact hole 210CT in the upper portion. As described above, the seventh connection electrode 1774 may be electrically connected to the fourth transistor T4 and the sixth transistor T6. Accordingly, the seventh connection electrode 1774 and the ninth connection electrode 1810 may electrically connect the pixel electrode of the light-emitting diode LED to the fourth transistor T4 and the sixth transistor T6.

A planarization layer 115 may cover the second source drain layer 1800. The planarization layer 115 may be an organic insulating layer including an organic insulating material such as acryl, benzocyclobutene (BCB), polyimide, or hexamethyldisiloxane (HMDSO).

The light-emitting diode LED may be disposed on the planarization layer 115. The light-emitting diode LED may include the pixel electrode 210 disposed on the planarization layer 115, an intermediate layer 220, and a common electrode 230. It is shown in FIG. 21 that the pixel electrodes 210 are used. For example, because the light-emitting diode includes the pixel electrode 210, the position of the pixel electrode 210 may be referred to as the position of the light-emitting diode. FIG. 21 shows, for convenience, the pixel electrodes 210 and the second source drain layer 1800 therebelow in an overlapping manner.

As shown in FIG. 21, the light-emitting diodes LED may be spaced apart from each other. It is shown in FIG. 21 that a second light-emitting diode LED2 overlapping the first pixel circuit PC1 and the second pixel circuit PC2 is electrically connected to a first pixel circuit PC1 disposed in an i-th row and a j-th column. For example, although the second light-emitting diode LED2 may be disposed on the imaginary line IML between the first pixel circuit PC1 and the second pixel circuit PC2, as shown in FIG. 21, the pixel electrode 210 of the second light-emitting diode LED2 may have a protrusion protruding in the −x direction and be electrically connected to the first pixel circuit PC1 through the contact hole 210CT formed in the planarization layer 115. Also, in other light-emitting diodes, the pixel electrode 210 may have a protrusion and be electrically connected to a corresponding pixel circuit through a contact hole 210CT thereunder in the protrusion.

Four third light-emitting diodes LED3 may be arranged around the second light-emitting diode LED2. It is shown in FIG. 21 that, in dotted lines of a quadrilateral shape representing a boundary of a set of the first pixel circuit PC1 and the second pixel circuit PC2, the third light-emitting diodes LED3 are disposed at four vertexes of the quadrilateral. For example, it is shown in FIG. 21 that a third light-emitting diode LED3 disposed at the lower right end is electrically connected to the second pixel circuit PC2 disposed in an i-th row and a (j+1)-th column, a third light-emitting diode LED3 disposed at the upper right end is electrically connected to a pixel circuit disposed in an (i−1)-th row and a (j+1)-th column and adjacent to the second pixel circuit PC2 in the +y direction, a third light-emitting diode LED3 disposed at the lower left end is electrically connected to a pixel circuit disposed in an i-th row and a (j−1)-th column and adjacent to the first pixel circuit PC1 in the −x direction, and a third light-emitting diode LED3 disposed at the upper left end is electrically connected to a pixel circuit disposed in an (i−1)-th row and a (j−1)-th column.

For example, a first light-emitting diode may be electrically connected to a pixel circuit adjacent to the first pixel circuit PC1 in the +y direction and disposed in an (i−1)-th row and a j-th column. In addition, first light-emitting diodes may be electrically connected to a pixel circuit adjacent to the second pixel circuit PC2 in the +x direction and disposed in an i-th row and a (j+2)-th column, a pixel circuit disposed in an i-th row and a (j−2)-th column, and a pixel circuit adjacent to the first pixel circuit PC1 in the −y direction and disposed in an (i+1)-th row and a j-th column. Similarly to the second light-emitting diode LED2, even in the case of the first light-emitting diode, four third light-emitting diodes LED3 may be arranged around the first light-emitting diode.

For example, pixel circuits arranged in the +x direction in an i-th row may be a case in which a set of a pixel circuit for a first light-emitting diode, a pixel circuit for a third light-emitting diode LED3, a pixel circuit for a second light-emitting diode LED2, and a pixel circuit for a third light-emitting diode LED3 is repeated. In addition, pixel circuits arranged in the y axis direction in a j-th column may be a case in which a set of a pixel circuit for a first light-emitting diode and a pixel circuit for a second light-emitting diode LED2 is repeated, and pixel circuits arranged in the second direction (e.g., the y axis direction) in each of a (j−1)-th column and a (j+1)-th column may be pixel circuits for a third light-emitting diode LED3.

As an example, a first light-emitting diode may be a diode emitting red light, a second light-emitting diode LED2 may be a diode emitting blue light, and a third light-emitting diode LED3 may be a diode emitting green light.

However, the arrangement of the light-emitting diodes is not necessarily limited to the above arrangement and may be variously modified.

The pixel electrode 210 may be a light-transmissive or a light-semitransmissive electrode or a reflective electrode. As an example, the pixel electrode 210 may include a reflective layer and a transparent or semi-transparent electrode layer on the reflective layer, wherein the reflective layer includes Ag, Mg, Al, Pt, Pd, Au, Ni, Nd, Ir, Cr, or compound thereof. The transparent or semi-transparent electrode layer may include at least one of indium tin oxide (ITO), indium zinc oxide (IZO), zinc oxide (ZnO_{X}: ZnO or ZnO₂), indium oxide (In₂O₃), indium gallium oxide (IGO), or aluminum zinc oxide (AZO). As an example, the pixel electrode 210 may have a three-layered structure of ITO/Ag/ITO.

A pixel-defining layer 119 may be disposed on the planarization layer 115. The pixel-defining layer 119 may prevent arcs and the like from occurring at the edge of the pixel electrode 210 by covering the edge of the pixel electrode 210 and increasing a distance between the pixel electrode 210 and the common electrode 230 over pixel electrode 210. For example, as shown in FIGS. 21 and 22, the pixel-defining layer 119 has an opening 119OP to expose the central portion of the pixel electrode 210. The exposed portion of the pixel electrode 210 may be defined as an emission area EA. The pixel-defining layer 119 may include an organic insulating material such as polyimide, an acrylic resin, benzocyclobutene, a phenolic resin, and the like and be formed by using spin coating and the like.

At least a portion of the intermediate layer 220 including an emission layer of the light-emitting diode LED may be disposed in the opening formed in the pixel-defining layer 119. The emission area of the light-emitting diode LED may be defined by the opening. The intermediate layer 220 may include the emission layer. The emission layer may include an organic material including a fluorescent or phosphorous material emitting red, green, blue, or white light. The emission layer may include a polymer organic material or a low molecular weight organic material. Functional layers may be selectively further disposed under and on the emission layer, the functional layers including a hole transport layer (HTL), a hole injection layer (HIL), an electron transport layer (ETL), and an electron injection layer (EIL).

Alternatively, the intermediate layer 220 may include a first stack including the emission layer and the functional layer, a second stack including the emission layer and the functional layer, and a charge generation layer between the first stack and the second stack. The charge generation layer may include a negative charge generation layer and a positive charge generation layer. The light-emission efficiency of a tandem type light-emitting diode LED including the plurality of emission layers, may be enhanced even more by the negative charge generation layer and the positive charge generation layer.

The negative charge generation layer may be an n-type charge generation layer. The negative charge generation layer may supply electrons. The negative charge generation layer may include hosts and dopants. The host may include an organic material. The dopant may include a metal material. The positive charge generation layer may be a p-type charge generation layer. The positive charge generation layer may supply holes. The positive charge generation layer may include hosts and dopants. The host may include an organic material. The dopant may include a metal material.

The emission layer may have a shape patterned to correspond to the pixel electrode 210. Layers of the intermediate layer 220 other than the emission layer may be an integral body over the plurality of pixel electrodes 210. However, various modifications may be made.

The common electrode 230 may be a light-transmissive electrode or a reflective electrode. As an example, the common electrode 230 may be a transparent or semi-transparent electrode and may include a metal thin film including Li, Ca, Al, Ag, Mg, or compound (e.g., LiF) thereof and having a small work function. In addition, the common electrode 230 may further include a transparent conductive oxide (TCO) layer such as ITO, indium zinc oxide (IZO), ZnO, ZnO₂, or In₂O₃ disposed on the metal thin film.

The common electrode 230 may be integrally formed over the entire surface of the display area DA to cover the display area DA and be disposed on the intermediate layer 220 and the pixel-defining layer 119. For example, each of the pixel electrodes 210 may be arranged to correspond to each light-emitting diode, and the common electrode 230 may be an integral body to correspond to the plurality of light-emitting diodes LED. The plurality of light-emitting diodes LED may share the common electrode 230. A stack structure of the pixel electrode 210, the intermediate layer 220, and the common electrode 230 may correspond to the light-emitting diode LED.

When needed, an encapsulation layer may be disposed on the light-emitting diode LED. The encapsulation layer may include a first inorganic encapsulation layer, a second inorganic encapsulation layer, and an organic encapsulation layer interposed therebetween.

As described above, the fifth conductive layer 1310 may be the second storage electrode CEs2 of the storage capacitor Cst, and simultaneously, be the first hold electrode CEh1 of the hold capacitor Chd. When an electrical potential of the second storage electrode CEs2 of the storage capacitor Cst becomes unstable in each pixel circuit, the first transistor T1, which is the driving transistor, might not accurately control the amount of current corresponding to a data signal DATA. This may result in the display device not being able to display high-quality images.

In contrast, in the display panel 10 and the electronic device 1 including the same, according to an embodiment, the silicon semiconductor layer 1110 is electrically connected to the driving voltage line PL as described above. In addition, the extension portion ETP of the silicon semiconductor layer 1110 is disposed between the first transistor T1 of the first pixel circuit PC1 and the first transistor T1 of the second pixel circuit PC2 in a plan view. For example, in a plan view, the extension portion ETP of the silicon semiconductor layer 1110 is disposed between the fifth conductive layer 1310 corresponding to the second node N2 of the first transistor T1 of the first pixel circuit PC1, and the fifth conductive layer 1310 corresponding to the second node N2 of the first transistor T1 of the second pixel circuit PC2. Accordingly, the extension portion ETP of the silicon semiconductor layer 1110 having an electrical potential of the driving voltage ELVDD, which is a constant voltage, or a similar voltage, may effectively prevent or minimize the second node N2 of the first pixel circuit PC1 and the second node N2 of the second pixel circuit PC2 from electrically affecting each other. Through this, the display panel 10 displaying high-quality images, and the electronic device 1 including the same may be implemented.

To effectively prevent the second node N2 of the first pixel circuit PC1 and the second node N2 of the second pixel circuit PC2 from electrically affecting each other, an end in the second direction (e.g., the y axis direction) of the extension portion ETP of the silicon semiconductor layer 1110 coincide with an end in the second direction (e.g., the y axis direction) of a portion of the fifth conductive layer 1310 adjacent to the extension portion ETP in the first pixel circuit PC1 and an end in the second direction (e.g., the y axis direction) of a portion of the fifth conductive layer 1310 adjacent to the extension portion ETP in the second pixel circuit PC2.

For example, as described above, the fifth transistors T5 in the first pixel circuit PC1 and the second pixel circuit PC2 include the main portion MP of the silicon semiconductor layer 1110 as an element. Accordingly, the fifth transistor T5 of the first pixel circuit PC1 may include a portion of the main portion MP disposed at one side of the extension portion ETP, for example, a portion of the main portion MP disposed in the −x direction with respect to the extension portion ETP. Similarly, the fifth transistor T5 of the second pixel circuit PC2 may include a portion of the main portion MP disposed at another side of the extension portion ETP, for example, a portion of the main portion MP disposed in the +x direction with respect to the extension portion ETP. In addition, each of two opposite ends of the main portion MP may be electrically connected to a corresponding first transistor T1 by the first connection electrode 1720 as described above.

Up to this point, various electronic devices 1, the display panel 10, and/or the display module 11 have been described, and each of the electronic devices 1, the display panel 10, and/or the display module 11 falls within the scope of the present disclosure.

While the present invention has been described with reference to various embodiments shown in the drawings, it will be understood by those of ordinary knowledge in the art that these are examples and various changes and equivalent other embodiments may be made therefrom.

What is claimed is:

1. A display panel, comprising:
first transistors arranged adjacent to each other in a first direction; and
a silicon semiconductor layer including a main portion extending in the first direction and an extension portion extending in a second direction crossing the first direction,
wherein the extension portion is disposed between the first transistors, in a plan view.

2. The display panel of claim 1, wherein each of the first transistors includes a first semiconductor layer and a first gate electrode disposed over the first semiconductor layer and overlapping the first semiconductor layer.

3. The display panel of claim 2, wherein the first semiconductor layer includes an oxide semiconductor.

4. The display panel of claim 2, further comprising a gate insulating layer covering the silicon semiconductor layer, wherein the first semiconductor layer is disposed over the gate insulating layer.

5. The display panel of claim 4, further comprising capacitor electrodes disposed between the gate insulating layer and the first semiconductor layer, wherein the capacitor electrodes are spaced apart from each other and correspond to the first transistors.

6. The display panel of claim 5, wherein, in the plan view, the extension portion is disposed between the capacitor electrodes.

7. The display panel of claim 5, wherein an end of the extension portion in the second direction coincides with an end in the second direction of a portion of each of the capacitor electrodes adjacent to the extension portion.

8. The display panel of claim 5, further comprising shield layers disposed between the capacitor electrodes and the first transistors.

9. The display panel of claim 8, wherein each of the shield layers is electrically connected to a corresponding capacitor electrode among the capacitor electrodes.

10. The display panel of claim 1, further comprising:
second transistors corresponding to the first transistors; and
data lines corresponding to the second transistors,
wherein each second transistor of the second transistors has a first end electrically connected to a corresponding data line among the data lines, and a second end electrically connected to a first gate electrode of a corresponding first transistor among the first transistors, and
wherein a second semiconductor layer of each of the second transistors is disposed on a same layer as a first semiconductor layer of each of the first transistors.

11. The display panel of claim 1, further comprising a driving voltage line electrically connected to the silicon semiconductor layer.

12. The display panel of claim 11, wherein the driving voltage line is disposed over the silicon semiconductor layer.

13. The display panel of claim 1, further comprising emission control transistors including a first portion of the main portion disposed at a first side of the extension portion, and a second portion of the main portion disposed at a second side of the extension portion,
wherein each of the emission control transistors is electrically connected to a corresponding first transistor among the first transistors.

14. The display panel of claim 13, further comprising connection electrodes electrically connecting each of the first and second portions of the main portion to a corresponding first transistor among the first transistors.

15. An electronic device, comprising:
a display panel; and
a lower cover forming an exterior of the electronic device, the lower cover including an opening exposing a portion of the display panel,
wherein the display panel includes:
first transistors arranged adjacent to each other in a first direction; and
a silicon semiconductor layer including a main portion extending in the first direction and an extension portion extending in a second direction crossing the first direction,
wherein the extension portion is disposed between the first transistors, in a plan view.

16. The electronic device of claim 15, wherein each of the first transistors includes a first semiconductor layer and a first gate electrode disposed over the first semiconductor layer and overlapping the first semiconductor layer.

17. The electronic device of claim 16, wherein the first semiconductor layer includes an oxide semiconductor.

18. The electronic device of claim 16, further comprising:
a gate insulating layer covering the silicon semiconductor layer, wherein the first semiconductor layer is disposed over the gate insulating layer; and
capacitor electrodes disposed between the gate insulating layer and the first semiconductor layer, spaced apart from each other, and corresponding to the first transistors.

19. The electronic device of claim 18, wherein, in the plan view, the extension portion is disposed between the capacitor electrodes.

20. The electronic device of claim 15, further comprising a driving voltage line electrically connected to the silicon semiconductor layer.
